(19) United States
(12) Patent Application Publication
(10) Pub. No.: US 2014/0197048 A1
(43) Pub. Date: Jul. 17, 2014

(54) MULTIPLE ORIENTATION SUPPORT FOR ELECTRONIC DEVICE WITH TOUCH SCREEN AND METHOD

(71) Applicant: Belkin International, Inc., Playa Vista, CA (US)

(72) Inventors: Erin Napolitano, Los Angeles, CA (US); Barry Sween, Santa Monica, CA (US); David Kleeman, Marina del Rey, CA (US); Xin Fu, Guangdong (CN); John Wadsworth, Burbank, CA (US); Colin Greenidge, Thousand Oaks, CA (US); Chetan Machakanoor, Culver City, CA (US); Justin Jakobson, Venice, CA (US)

(73) Assignee: Belkin International, Inc., Playa Vista, CA (US)

(21) Appl. No.: 14/213,343

(22) Filed: Mar. 14, 2014

Related U.S. Application Data
(63) Continuation-in-part of application No. 14/184,408, filed on Feb. 19, 2014.
Application No. 14/184,408 is a continuation of application No. 13/568,040, filed on Aug. 6, 2012, now Pat. No. 8,684,174.
Application No. 13/568,040 is a continuation of application No. 12/782,592, filed on May 18, 2010, now Pat. No. 8,235,208.
Application No. 12/782,592 is a continuation of application No. 11/810,823, filed on Jun. 6, 2007, now Pat. No. 7,735,644.
(60) Provisional application No. 61/799,277, filed on Mar. 15, 2013.

(51) Int. Cl. H05K 5/02

(52) U.S. Cl. CPC H05K 5/0226
USPC 206/45.2; 53/201

(57) ABSTRACT

Apparatus for supporting a tablet computer or an electrical device having a touch screen in multiple orientations, the apparatus including a substantially planar base, a back member, a first hinge attaching the back member to the base, a cover configured to hold the electrical device, and a connector that attaches the cover to the back member. The connector can include at least one alignment piece that aligns the cover to the back member only in certain predefined orientations including a landscape orientation and a portrait orientation, and the alignment piece inhibits the cover from being rotated about an axis perpendicular to the cover relative to the back member when the cover is attached to the back member with the connector, but the connector allows the cover to be detached from the back member and reattached in a different one of the predefined orientations.

### RELATED PATENT APPLICATIONS

This patent application is a non-provisional patent application of U.S. Provisional Patent Application No. 61/799,277, filed Mar. 15, 2013, which is incorporated herein by reference. This patent application is also a continuation-in-part patent application of U.S. patent application Ser. No. 14/184,408, filed Feb. 19, 2014, which is a continuation patent application of U.S. patent application Ser. No. 13/568,040, filed Aug. 6, 2012, which is a continuation of U.S. patent application Ser. No. 12/782,592, filed May 18, 2010, which is a continuation application of U.S. patent application Ser. No. 11/810,823, now U.S. Pat. No. 7,735,644, filed Jun. 6, 2007.

### FIELD OF THE INVENTION

This invention relates generally to supports and cases for electrical devices, and relates more particularly to such supports and cases that are configured for supporting electrical devices that have touch screens, that are configured for supporting electrical devices in multiple orientations (e.g., landscape and portrait), or both, and methods concerning same.

### BACKGROUND OF THE INVENTION

Advancing technology has made portable electrical devices increasingly popular and has given such electrical devices an ever-increasing array of capabilities. Some electrical devices, such as digital music and video players, cellular phones, personal digital assistants, handheld digital computers, tablet computers, and the like, include the capability to display images or videos. While it is possible to view the images or videos while holding such video-capable devices in one's hand, it would often be more convenient and more comfortable to set down such electrical devices and have them maintain a position in which the images and videos can be viewed easily.

Furthermore, most portable electrical devices include display or touch screens and/or control mechanisms. It would be convenient for the user of such electrical devices if a support or case allowed easy viewing of the display screen and operation of the electrical device, without requiring the user to hold the electrical device or remove it from the case.

Accordingly, a need or potential for benefit exists for a support or case for an electrical device that allows it to maintain a hands-free operating and viewing position.

### BRIEF DESCRIPTION OF THE DRAWINGS

The invention will be better understood from a reading of the following detailed description of examples of embodiments, taken in conjunction with the accompanying figures in the drawings in which:

FIG. 1 is a bottom, side isometric view of a case in a first embodiment of an open configuration and enclosing an electrical device, according to a first embodiment of the case;

FIG. 2 is a top, front, side isometric view of the case of FIG. 1 in a second embodiment of an open configuration, according to the first embodiment of the case;

FIG. 3 is a top, back, side isometric view of the case of FIG. 1 in a third embodiment of an open configuration, according to the first embodiment of the case;

FIG. 4 is a side view of the case of FIG. 1 in a closed configuration and enclosing the electrical device of FIG. 1, according to the first embodiment of the case;

FIG. 5 is another top, front, side isometric view of the case of FIG. 1 in a fourth embodiment of an open configuration and enclosing the electrical device of FIG. 1, according to the first embodiment of the case;

FIG. 6 is a cross-sectional view along line I-I of FIG. 2 of the case of FIG. 1 in the second embodiment of an open configuration, according to the first embodiment of the case;

FIG. 7 is a side view of a case in an open configuration and enclosing an electrical device, according to a second embodiment of the case;

FIG. 8 is a top, front, side isometric view of a case in a first embodiment of an open configuration and enclosing an electrical device, according to a third embodiment of the case;

FIG. 9 is a top, back, side isometric view of the case of FIG. 8 in a second embodiment of an open configuration, according to the third embodiment of the case;

FIG. 10 is bottom, side isometric view of the case of FIG. 8 in a third embodiment of an open configuration, according to the third embodiment of the case;

FIG. 11 is a flow chart for an embodiment of a method of using a case with an electrical device;

FIG. 12 is a perspective right-side front view of an example of an apparatus for supporting an electrical device having a touch screen, the apparatus configured to hold the electrical device in a landscape orientation;

FIG. 13 is a perspective right-side rear view of the apparatus of FIG. 12, the apparatus configured to hold the electrical device in the landscape orientation;

FIG. 14 is a perspective right-side front view of the apparatus for supporting an electrical device having a touch screen of FIGS. 12 and 13, the apparatus configured in FIG. 14 to hold the electrical device in a portrait orientation;

FIG. 15 is a perspective right-side rear view of the apparatus for supporting an electrical device having a touch screen of FIGS. 12 to 14, the apparatus configured to hold the electrical device in the portrait orientation;

FIG. 16 is a perspective view of the apparatus for supporting an electrical device having a touch screen of FIGS. 12 to 15, the apparatus shown folded into a case for holding the electrical device;

FIG. 17 is a perspective right-side front view of the apparatus for supporting an electrical device having a touch screen of FIGS. 12 to 16, the apparatus shown with the cover for holding the electrical device omitted, revealing part of the connector that attaches the cover to the back member of the apparatus;

FIG. 18 is a perspective view of the cover for holding the electrical device of the apparatus for supporting an electrical device having a touch screen of FIGS. 12 to 16, the remainder of the apparatus omitted, revealing part of the connector that attaches the cover to the back member;

FIG. 19 is a detailed perspective view of part of a connector that attaches the cover to the back member of an apparatus for supporting an electrical device having a touch screen, the connector being configured to align the cover to the back member only in certain predefined orientations, the part of the connector of FIG. 19 being committedly connected to the back member;

FIG. 20 is a detailed perspective view of part of a connector that attaches the cover to the back member of an apparatus for supporting an electrical device having a touch screen, the connector being configured to align the cover to the back member only in certain predefined orientations, the part of the connector of FIG. 20 being committedly connected to the cover and configured to mate with the part of the connector of FIG. 19;

FIG. 21 is a detailed perspective view of another embodiment of a connector that attaches the cover to the back member of an apparatus for supporting an electrical device having a touch screen, the connector being configured to align the cover to the back member only in certain predefined orientations, this connector having a non-circular recess and a non-circular protrusion that mates with the recess;

FIG. 22 is a detailed perspective view of part of another embodiment of a connector that attaches the cover to the back member of an apparatus for supporting an electrical device having a touch screen, the connector being configured to align the cover to the back member only in certain predefined orientations, this connector including a ring that can be concentric with the center of the connector;

FIG. 23 is a detailed side view of the ring of FIG. 22 along with a second mating ring that is another part of a connector that attaches the cover to the back member of an apparatus for supporting an electrical device having a touch screen, the connector being configured to align the cover to the back member only in certain predefined orientations, this view illustrating the rings of the connector when the cover and the back member are in one of the certain predefined orientations;

FIG. 24 is a detailed side view of the rings of FIG. 23 illustrating the rings of the connector when the cover and the back member are not in one of the certain predefined orientations; and

FIG. 25 is a perspective right-side front view of an example of an apparatus for supporting an electrical device having a touch screen, the apparatus configured to hold the electrical device in a landscape orientation, the apparatus having a hand strap.

For simplicity and clarity of illustration, the drawing figures illustrate the general manner of construction, and descriptions and details of well-known features and techniques may be omitted to avoid unnecessarily obscuring the invention. Additionally, the same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Furthermore, the terms “include,” and “have,” and any variations thereof, are intended to cover a non-exclusive inclusion, such that a process, method, system, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical, physical, mechanical, or other manner. The term “on,” as used herein, is defined as on, at, or otherwise adjacent to or next to or over.

### DETAILED DESCRIPTION OF EXAMPLES OF EMBODIMENTS

Various embodiments provide an apparatus for supporting, in multiple orientations, an electrical device having a touch screen. In a number of embodiments, the apparatus includes a substantially planar base, a back member, a first hinge attaching the back member to the base, a cover configured to hold the electrical device, and a connector. In various embodiments, the connector attaches the cover to the back member and includes at least one alignment piece that aligns the cover to the back member only in certain predefined orientations, the predefined orientations including a landscape orientation and a portrait orientation. Moreover, in a number of embodiments, the alignment piece inhibits the cover from being rotated about an axis perpendicular to the cover relative to the back member when the cover is attached to the back member with the connector, but the connector allows the cover to be detached from the back member and reattached in a different one of the predefined orientations.

In some embodiments, the cover includes a center and the connector is located at the center of the cover. Further, in a number of embodiments, the connector includes a first piece committedly connected to the cover and a second piece committedly connected to the back member, and the first piece is separated from the second piece when the cover is detached from the back member. Further still, in some embodiments, the first piece has a central first axis, the second piece has a central second axis, the first axis and the second axis are in common when the cover is attached to the back member by the connecter. Even further, in some embodiments, the first piece has a first magnet concentric with the first axis and the second piece has a second magnet concentric with the second axis, and when the cover is attached to the back member by the connecter, the first magnet is magnetically bonded to the second magnet. Even further still, in particular embodiments, the alignment piece is concentric with the first axis and the second axis when the cover is attached to the back member by the connecter and the first magnet is magnetically bonded to the second magnet.

In various embodiments, the connector includes at least one magnet, and the at least one magnet holds the connector in the predefined orientations. In some embodiments, for example, the cover includes a center and the at least one magnet includes a first magnet concentric with the center of the cover. Further, in different embodiments, at least one magnet includes a first magnet and either a second magnet or a piece of iron or magnetic steel, as examples. Even further, in some embodiments, the first magnet significantly bonds with the second magnet or the piece of iron or magnetic steel only when the cover is aligned to the back member, for instance, in the certain predefined orientations.

In certain embodiments, the connector includes a center and the at least one alignment piece includes multiple outer tabs and multiple inner tabs. In some embodiments, for example, the outer tabs alternate with the inner tabs, and in a number of embodiments, the outer tabs extend further radially from the center than the inner tabs. Moreover, in particular embodiments, the outer tabs are equally spaced around the center, the inner tabs are equally spaced around the center, or both. Further, in some embodiments, the at least one alignment piece includes four of the outer tabs and four of the inner tabs.

Further, in some embodiments, the at least one alignment piece includes an outer ring and an inner recess. In particular embodiments, for example, the outer ring includes alternating notches and protrusions spaced around the outer ring. Even further, in certain embodiments, a first radial distance from the center of the connector to a first inner side of the protrusions is less than a second radial distance from the center of the connector to a second inner side of the notches. Still further, in some embodiments, the outer tabs fit within the inner recess at the notches, and the inner tabs fit within the inner recess at the protrusions, but the outer tabs do not fit within the inner recess at the protrusions.

Even further, in some embodiments, the connector includes a center and the at least one alignment piece includes a non-circular recess concentric with the center and a mating non-circular protrusion. In various embodiments, the protrusion mates with the recess in a first orientation and a second orientation, and the first orientation and the second orientation are 90 degrees apart. Moreover, in various embodiments, the apparatus further includes a hand strap.

Still further, in some embodiments, the connector includes a center and the at least one alignment piece includes a first ring concentric with the center of the connector. In certain embodiments, for example, the first ring includes alternating protrusions and toughs extending around the center of the connector. Moreover, in particular embodiments, the first ring includes multiple magnets located in the toughs around the center of the connector. Furthermore, in specific embodiments, the first ring includes at least four toughs around the center of the connector, for example. Even further still, in some embodiments, the at least one alignment piece includes a second ring concentric with the center of the connector. In particular embodiments, the second ring includes alternating protrusions and toughs extending around the center of the connector. Further, in certain embodiments, the second ring mates with the first ring with protrusions of the first rings in troughs of the second ring and protrusions of the second rings in troughs of the first ring.

Further embodiments provide a method of obtaining, providing, or manufacturing an apparatus for supporting an electrical device having a touch screen in multiple orientations. In a number of embodiments, such a method includes at least the acts of obtaining, providing, or manufacturing a base, obtaining, providing, or manufacturing a back member attached to the base, obtaining, providing, or manufacturing a cover configured to hold the electrical device, and obtaining, providing, or manufacturing a connector. In a number of embodiments, the connector attaches the cover to the back member and aligns the cover to the back member only in certain predefined orientations, the predefined orientations including a landscape orientation and a portrait orientation. Further, in various embodiments, the connector inhibits the cover from being rotated about an axis perpendicular to the cover relative to the back member when the cover is attached to the back member with the connector, but the connector allows the cover to be detached from the back member and reattached in multiple of the predefined orientations.

Various embodiments provide an apparatus for supporting a tablet computer from a user's leg that includes a substantially planar base, a substantially planar lower back member, a first hinge attaching the lower back member to the base, an upper back member, a second hinge attaching the upper back member to the lower back member, and a leg-conforming region having a rounded edge configured to conform around the top of one of the user's legs. In some embodiments, the upper back member is substantially planar. Further, in particular embodiments, when the first hinge and the second hinge are unfolded so that the apparatus is laid flat, the apparatus is substantially planar. Even further, in some embodiments, the base includes at least a first part of the rounded edge. Further still, in some embodiments, the lower back member includes at least a second part of the rounded edge. Even further still, in some embodiments, the leg-conforming region extends across the first hinge from the base to the lower back member.

In a number of embodiments, apparatus includes a flexible top layer, a flexible bottom layer, and a stiff layer located between the top layer and the bottom layer. Moreover, in particular embodiments, the top layer and the bottom layer extend from the base to the upper back member through the lower back member, and the stiff layer is broken at the first hinge and at the second hinge to allow bending of the apparatus at the first hinge and at the second hinge. Furthermore, in certain embodiments, the rounded edge is formed within the stiff layer.

In different embodiments, the leg-conforming region includes a flexible material, an elastic material, or a hole through the apparatus without any material. Further, in some embodiments, the leg-conforming region includes a center and the first hinge extends through the center of the leg-conforming region. Even further, in some embodiments, the second hinge is parallel to the first hinge. Further still, some embodiments include a third hinge, for example, extending through the base. In certain embodiments, for instance, the third hinge is substantially parallel to the first hinge and to the second hinge. Even further still, in a number of embodiments, without considering the leg-conforming region, the base is rectangular, the lower back member is rectangular, the upper back member is rectangular, when the first hinge and the second hinge are unfolded so that the apparatus is laid flat, the apparatus is rectangular, or a combination thereof. Moreover, in particular embodiments, when the first hinge and the second hinge are unfolded so that the apparatus is laid flat, the apparatus has rounded corners. Furthermore, in certain embodiments, the apparatus further includes a hand strap.

Still other embodiments include an apparatus for supporting an electronic device from a user's leg, the apparatus including: a flexible top layer, a flexible bottom layer, a stiff layer located between the top layer and the bottom layer, at least one hinge, wherein the stiff layer is broken at the hinge to allow bending of the apparatus at the hinge, and a leg-conforming region having a rounded edge configured to conform around the top of the user's leg, wherein the rounded edge is formed within the stiff layer. In a number of embodiments, the leg-conforming region extends across the hinge of the apparatus.

Yet other embodiments include a method of obtaining, providing, or manufacturing an apparatus for supporting an electronic device from a user's leg. Such a method can include, for example, at least the acts of: obtaining, providing, or manufacturing a base, obtaining, providing, or manufacturing a lower back member, obtaining, providing, or manufacturing a first hinge attaching the lower back member to the base, and obtaining, providing, or manufacturing a leg-conforming region having a rounded edge configured to conform around the top of one of the user's legs, wherein the leg-conforming region extends across the first hinge from the base to the lower back member.

In a number of embodiments, a case for an electrical device can include: (a) a first portion with a bottom surface; (b) a second portion adjacent to the first portion; (c) a third portion adjacent to the second portion; (d) a fourth portion adjacent to the third portion; and (e) a fifth portion with an interior surface and adjacent to the fourth portion. In this embodiment, at least one of the first portion or the third portion is configured to be removably coupled to the electrical device. Additionally, when the case is placed in an open configuration, the first portion is capable of being located over the fifth portion with the bottom surface of the first portion adjacent to the interior surface of the fifth portion.

In other embodiments, a holder for an electrical device can include: (a) an inner section with a bottom surface; (b) a first outer section adjacent to the inner section; (c) a second outer section with a first surface and adjacent to the first outer section; and (d) one or more ribs adjacent to the first surface of the second outer section. In these embodiments, the holder is configured to be removably coupled to the electrical device. Furthermore, the holder is configured to be placed in a position such that the inner section forming a substantially non-zero angle with the second outer section and the bottom surface of the inner section is at least partially supported by the first surface of the second outer section and one rib of the one or more ribs.

In yet another embodiment, a method of using a case with an electrical device includes: (a) providing the case to comprise: (1) a first portion with a bottom surface; (2) a second portion adjacent to the first portion; (3) a third portion adjacent to the second portion; (4) a fourth portion adjacent to the third portion; and (5) a fifth portion with an interior surface adjacent to the fourth portion; (b) coupling the electrical device to the case at the first portion; (c) placing the case in an open configuration with the bottom surface of the first portion over and adjacent to the interior surface of the fifth portion.

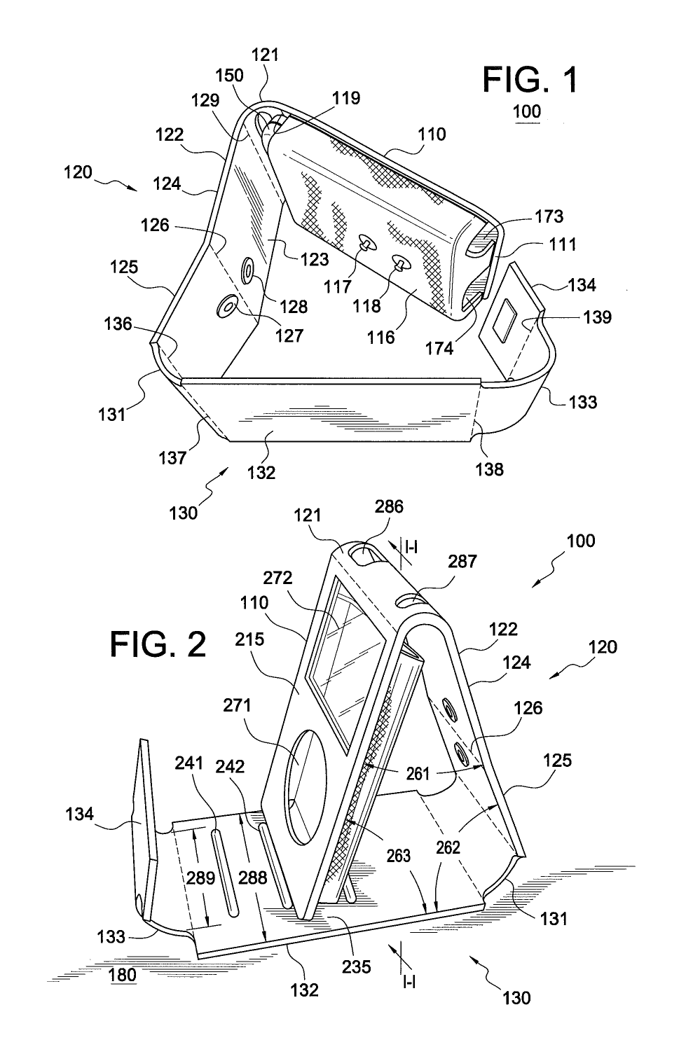

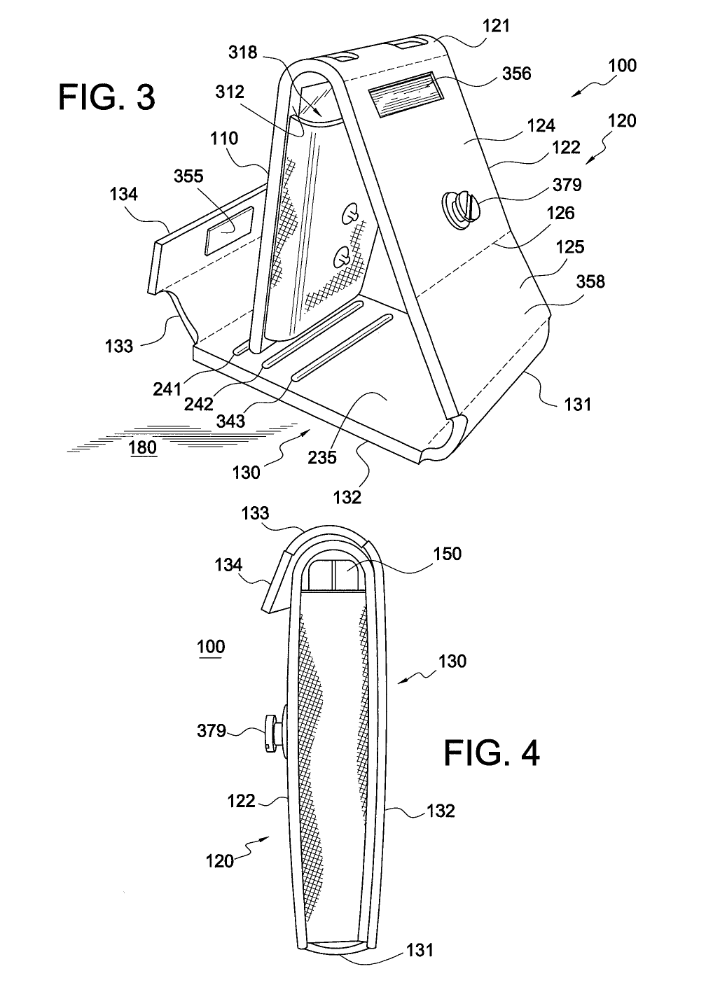

Turning to the drawings, FIG. 1 illustrates a bottom, side isometric view of a case 100 in a first embodiment of an open configuration and enclosing an electrical device 150, according to a first embodiment of case 100. FIG. 2 illustrates a top, front, side isometric view of case 100 in a second embodiment of an open configuration, according to the first embodiment of case 100. FIG. 3 illustrates top, back, side isometric view of case 100 in a third embodiment of the open configuration, according to the first embodiment of case 100. FIG. 4 illustrates a side view of case 100 in a closed configuration and enclosing electrical device 150, according to the first embodiment of case 100. Case 100 is merely exemplary and is not limited to the embodiments presented herein. Case 100 can be employed in many different embodiments or examples not specifically depicted or described herein.

In some embodiments, a holder or case 100 for electrical device 150 can include: (a) an inner portion 110 with a bottom surface 111; (b) an outer section 120 adjacent to inner portion 110; (c) an outer section 130 adjacent to outer section 120; and (d) one or more supports or ribs 241, 242, and 343 adjacent to outer section 130.

In some embodiments, case 100 can also include a connector 379 at an exterior surface 358 of outer section 120. As an example, connector 379 can be configured to couple to a clip (not shown) on a belt.

Case 100 is configured to be removably coupled to electrical device 150. In one example, inner portion 110 is configured to be coupled to electrical device 150. In alternative embodiments, outer section 120 is configured to be coupled to electrical device 150.

In one embodiment, outer section 120 can include: (a) a portion 121 adjacent to inner portion 110; and (b) a portion 122 adjacent to portion 121. Portion 122 can include an interior surface 123.

In various embodiments, at least a part of inner portion 110 can be contiguous with and/or continuous with at least a part of portion 121. Likewise, at least a part of portion 121 can be contiguous with and/or continuous with at least a part of portion 122. Furthermore, in some embodiments, inner portion 110 can be coupled to portion 121 at or by a hinge 119 with inner portion 110 and portion 121 configured to be folded along hinge 119. Likewise, portion 121 can be coupled to portion 122 at or by a hinge 129 with portions 121 and 122 configured to be folded along hinge 129.

In the same or a different embodiment, outer section 130 can include: (a) a portion 131 adjacent to portion 122; (b) a portion 132 with an interior surface 235 and adjacent to portion 131; (c) a portion 133 adjacent to portion 132; and (d) a portion 134 adjacent to portion 133. In one embodiment, ribs 241, 242, and 343 are adjacent to interior surface 235.

In many embodiments, at least a part of portion 131 can be contiguous with and/or continuous with at least a part of portion 122. Likewise, at least a part of portion 131 can be contiguous with and/or continuous with at least a part of portion 132. In the same or different embodiments, at least a part of portion 132 can be contiguous with and/or continuous with at least a part of portion 133. Additionally, in some embodiments, at least a part of portion 133 can be contiguous with and/or continuous with at least a part of portion 134.

In some examples, portion 122 can be coupled to portion 131 at or by a hinge 136 with portions 122 and 131 configured to be folded along hinge 136. Likewise, portion 131 can be coupled to portion 132 at or by a hinge 137 with portions 131 and 132 configured to be folded along hinge 137. In the same or different embodiments, portion 132 can be coupled to portion 133 at or by a hinge 138 with portions 132 and 133 configured to be folded along hinge 138. In some embodiments, portion 133 can be coupled to portion 134 at or by a hinge 139 with portions 133 and 134 configured to be folded along hinge 139. In some embodiments, hinges 119, 129, 136, 137, 138, and/or 139 are rows of stitching that extend across the width of case 100. In other embodiments, hinges 119, 129, 136, 137, 138, and/or 139 are fold lines or a region where two different materials are coupled together. In still other embodiments, case 100 does not include some of or any of hinges 119, 129, 136, 137, 138, or 139, and one or more of portions 121, 131, and 133 serve as the hinges.

In some embodiments, portion 132 can have a width 288, and portion 133 can have a width 289. In some examples, width 289 is less than width 288. For example, width 288 can be four to ten centimeters, and width 289 can be two to six centimeters. In a preferred example, width 288 is approximately six and a half centimeters, and width 289 is approximately five centimeters. Likewise, widths of portions 110, 121, 122, 131, 132, and 134 can be the same at four to ten centimeters. In a preferred example, widths of portions 110, 121, 122, and 132 are each also six and a half centimeters, and width of portion 131 is approximately five and a half centimeters.

In the same or different embodiments, width 289 is less than width 288, and portion 121 can have at least one aperture 287 to allow a user access to electrical device 150 when case 100 is in a closed configuration. Portion 121 can also allow the user access to electrical device 150 though aperture 287 and one or more apertures 286 when case 100 is in an open configuration.

Case 100 is configured to be placed in open or closed configurations. FIG. 1 illustrates case 100 in a first embodiment of the open configuration. FIGS. 2 and 3 illustrate case 100 in second and third embodiments of the open configuration on a flat surface 180, and FIG. 4 illustrates case 100 in the closed configuration. In the illustrated embodiments, when case 100 is in a closed configuration, outer section 130 wraps around inner portion 110 such that an exterior surface 215 of inner portion 110 contacts and/or is adjacent to interior surface 235.

In some embodiments, electrical device 150 includes: (a) a first side (not shown); (b) a second side (not shown) opposite the first side; and (c) a third side (not shown) adjacent to the first side and the second side. In various examples, the second side of electrical device 150 can include a video screen and/or a control mechanism. When case 100 is placed in a closed configuration and encases electrical device 150, portion 121 is adjacent to the third side of electrical device 150, portion 122 is adjacent to the first side of electrical device 150, and inner portion 110 is adjacent to the second side of electrical device 150.

In some examples, portion 134 can include a coupling mechanism 355, and portion 122 can include a coupling mechanism 356, as shown in FIG. 3. Coupling mechanism 355 can be designed to be coupled to coupling mechanism 356. In some embodiments, attaching coupling mechanisms 355 and 356 to each other secures case 100 in a closed configuration. In alternative embodiments, portion 133 includes a first coupling mechanism and portion 121 includes a second coupling mechanism. In this alternative embodiment, the first coupling mechanism is configured to be coupled to the second coupling mechanism to secure case 100 in a closed configuration.

In some embodiments, coupling mechanism 355 can include one or more connectors that can be coupled to one or more of complementary connectors forming coupling mechanism 356. In one embodiment, coupling mechanisms 355 and 356 are complementary Velcro® material. In other embodiments, coupling mechanisms 355 and 356 can be buttons, string ties, or the like. In some examples, coupling mechanisms 355 and 356 can also contain magnets to help align and couple coupling mechanisms 355 and 356.

In various embodiments, as shown in FIGS. 2 and 3, when case 100 is in the open configuration, the case is configured to be placed in a position such that bottom surface 111 is at least partially supported by interior surface 235 and at least one rib of ribs 241, 242, and 343. Moreover, in this configuration, inner portion 110 forms a non-zero angle 261 with portion 122; portion 122 forms a non-zero angle 262 with portion 132; and portion 132 forms a non-zero angle 263 with inner portion 110. In some embodiments, angles 261, 262, and 263 can be acute angles of a single triangle.

In one example, when bottom surface 111 is partially supported by rib 343, angle 261 can be approximately 30 degrees; angle 262 can be approximately 75 degrees; and angle 263 can be approximately 75 degrees. In the same or a different example, as shown in FIG. 2, when bottom surface 111 is partially supported by rib 242, angle 261 can be approximately 40 degrees; angle 262 can be approximately 70 degrees; and angle 263 can be approximately 70 degrees. Likewise, as shown in FIG. 3, when bottom surface 111 is partially supported by rib 241, angle 261 can be approximately 50 degrees; angle 262 can be approximately 65 degrees; and angle 263 can be approximately 65 degrees.

In other examples, angles 261, 262, and/or 263 are set such that inner portion 110 is at a comfortable viewing or operating position for a user of electrical device 150. In some embodiments, angles 261, 262, and/or 263 can be fixed to complement the features of electrical device 150. For example, if electrical device 150 is mostly used for viewing images or videos, angles 261, 262, and 263 can be different than if the user's interaction with electrical device 150 is mainly to change settings on a touch screen of electrical device 150.

In the same or different examples, portion 121 and portion 132 can provide support to inner portion 110 when case 100 is in the open configuration and inner portion 110 is located over portion 132 with bottom surface 111 adjacent to interior surface 235.

Referring again to FIGS. 1-4, inner portion 110 can include: (a) bottom surface 111; (b) an interior surface 312 adjacent to bottom surface 111; (c) exterior surface 215 adjacent to bottom surface 111 and opposite interior surface 312; and (d) a coupling mechanism 116 at interior surface 312. In some embodiments, when case 100 is placed in a closed configuration, exterior surface 215 is substantially parallel and/or adjacent to interior surface 235.

In some examples, interior surface 312 is configured to be removably coupled to electrical device 150. In one embodiment, interior surface 312 is removably coupled to electrical device 150 using coupling mechanism 116.

Coupling mechanism 116 can be configured to removably enclose electrical device 150. In some examples, coupling mechanism 116 can be a pocket. When coupling mechanism 116 is a pocket, electrical device 150 can be placed inside of coupling mechanism 116 through an opening 318 in coupling mechanism 116. In one embodiment, coupling mechanism 116 is a piece of material sewn or otherwise attached to three sides of interior surface 312. Opening 318 can be located at the unattached side of the material. In some examples, opening 318 is located opposite to bottom surface 111. In some examples, coupling mechanism 116 can include one or more apertures 173 and 174 to allow the user access to portions of electrical device 150. In one embodiment, apertures 173 and 174 allow the user to connect peripheral devices such as headphones or power supplies to electrical device 150 without removing electrical device 150 from case 100. In alternative embodiments, coupling mechanism 116 can be Velcro® material, strings ties, buttons, or the like.

Inner portion 110 can allow a user to view and use electrical device 150 when electrical device 150 is coupled to interior surface 312 and case 100 is in the open configuration. In one example, inner portion 110 can include one or more openings 271 and 272 to allow the user to view and use electrical device 150. In some examples, opening 272 can be covered by a clear material. The clear material can allow the user to view and/or touch a display or touch screen at the second side of electrical device 150, while protecting the screen from damage. In one example, the clear material is a clear plastic, for example, clear polyvinyl chloride (PVC).

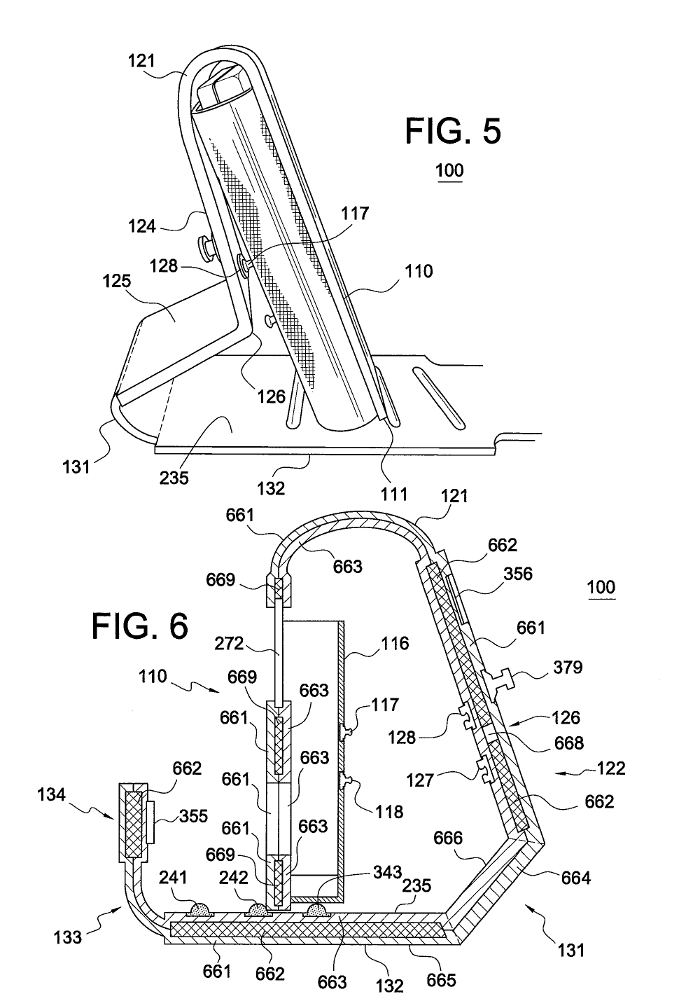

FIG. 5 illustrates a top, front, side isometric view of case 100 in a fourth embodiment of the open configuration, according to the first embodiment of case 100. As shown in FIGS. 1, 2, 3, and 5, portion 122 can include: (a) a segment 124 adjacent to portion 121; (b) a segment 125 adjacent to segment 124 and portion 131. In some examples, a bend region 126 separates and/or couples segment 124 from segment 125. Segment 124 is configured to be bent relative to segment 125 at bend region 126. In various examples, allowing segment 124 to be bent relative to segment 125 can increase the stability of case 100 when case 100 is in the open configuration and inner portion 110 is located over portion 132 with bottom surface 111 adjacent to interior surface 235.

In some embodiments, inner portion 110 can further include attachment mechanisms 117 and 118. In the same embodiment, portion 121 can include attachment mechanisms 127 and 128. Attachment mechanism 117 can include one or more connectors that can be coupled to one or more complementary connectors forming attachment mechanism 128. Likewise, attachment mechanism 118 can include one or more connectors that can be coupled to one or more complementary connectors forming attachment mechanism 127.

In one embodiment, attachment mechanisms 117 and 118 can be identical to or substantially similar to coupling mechanism 355. Moreover, attachment mechanisms 127 and 128 can be identical to or substantially similar to coupling mechanism 356.

In one example, attachment mechanisms 117 and 118 are adjacent to coupling mechanism 116. In the same or different embodiments, attachment mechanisms 127 and 128 are located at segments 125 and 124, respectively. In some examples, attachment mechanisms 117 and 118 can be male buttons, and attachment mechanisms 127 and 128 can be female buttons. In other embodiments, attachment mechanisms 117, 118, 127, and 128 are Velcro® material, strings ties, magnets, or the like.

Attachment mechanisms 117 and 118 can be coupled to attachment mechanisms 128 and 127, respectively, when case 100 is in a closed configuration. As shown in FIG. 5, attachment mechanism 117 can also be capable of being coupled to attachment mechanism 128 when case 100 is in open configuration and inner portion 110 is located over portion 132 with bottom surface 111 adjacent to interior surface 235. In some embodiments, segment 124 bends relative to segment 125 at bent region 126 when attachment mechanism 117 is coupled to attachment mechanism 128 and case 100 is in the open configuration with bottom surface 111 adjacent to interior surface 235. In alternative embodiments, attachment mechanisms 117 and 118 can both be coupled to attachment mechanisms 128 and 127, respectively, when case 100 is in the open configuration and inner portion 110 is located over portion 132 with bottom surface 111 adjacent to interior surface 235.

Referring back to FIGS. 2 and 3, interior surface 235 of portion 132 can include ribs 241, 242, and 343. In some examples, one or more of ribs 241, 242, and 343 extend in first direction and are substantially parallel to each other. In various embodiments, the first direction is substantially parallel to width 288 of interior surface 235 embodiments. In some examples, ribs 241, 242, and 343 extend approximately 70 to 90 percent of width 288 and have a thickness of two to four millimeters.

In various embodiments, rib 241 is separated from rib 242 by approximately ten to twenty millimeters. For example, rib 241 can be separated from rib 242 by fifteen millimeters. In the same or different examples, rib 242 can be separated from rib 343 by ten to twenty millimeters. In some embodiments, the distance between ribs 241, 242, and 343 is set based on the dimensions of electrical device 150. In some examples, the distances between adjacent ribs are the same. In other embodiments, the distance between adjacent ribs varies.

FIG. 6 illustrates a cross-sectional view along line I-I (FIG. 2) of case 100, according to the first embodiment of case 100. In the embodiment illustrated in FIG. 6, portion 132 can include: (a) an outer layer 661 with an exterior surface 665; (b) a stiffener layer 662 coupled to outer layer 661; (c) an inner layer 663 with interior surface 235 and coupled to stiffener layer 662.

In one embodiment, outer layer 661 and inner layer 663 can extend continuously through portions 133 and 134. However, in the embodiment illustrated in FIG. 6, portion 134 includes stiffener layer 662, but portion 133 does not include stiffener layer 662. In some examples, stiffener layer 662 is not present in portion 133 to allow easier folding of case 100 between the open and closed configurations.

In the embodiment illustrated in FIG. 6, portion 131 includes; (a) an inner layer 666; and (b) an outer layer 664. In some embodiments, inner layer 666 and outer layer 664 are made from different material than inner layer 663 and outer layer 661, respectively. In the same or a different embodiment, inner layer 666 and outer layer 664 are made from the same material. In alternative embodiments, portion 131 can include a stiffener layer. In the same or different examples, portion 131 can be made from the same material as coupling mechanism 116.

Portion 122 can include: (a) outer layer 661; (b) inner layer 663; and (c) stiffener layer 662 present throughout portion 122 except at bend region 126. In some embodiments, at bend region 126, a void region 668 exists between inner layer 663 and outer layer 661 to facilitate folding at bend region 126.

In the same or different embodiments, portion 121 can include: (a) outer layer 661; and (b) inner layer 663 coupled to outer layer 661. In alternative embodiments, portion 121 can include stiffener layer 662 between outer layer 661 and inner layer 663.

In inner portion 110, outer layer 661 and inner layer 663 can extend around the edges of openings 271 and 272. In some embodiments, inner portion 110 can include a stiffener layer 669. In many examples, stiffener layer 669 can be made from a different material than stiffener layer 662. For example, stiffener layer 662 can be composed of a material that provides more cushioning and protection than stiffener layer 669. In alternative embodiments, stiffener layers 662 and 669 can be made from the same material.

In an alternative example, portions 134, 132, 122, and/or 110 do not include a stiffener layer, or portions 110, 121, 122, 131, 132, 133, and 134 all include a stiffening layer. In yet another embodiment, inner portion 110, outer section 120, and/or outer section 130 are formed by a single layer (e.g., outer layer 661 or inner layer 663). In the same or different embodiments, coupling mechanism 116 can also include a stiffener layer.

Referring again to FIG. 6, outer layers 661 and 664 can be composed of a first material, and inner layers 663 and 666 can be composed of a second material. In some embodiments, outer layers 661 and 664 and inner layers 663 and 666 are made of leather (for example, split leather), suede, PVC, polyurethane, nylon, fabric, or the like. Stiffener layers 662 and 669 can be composed of cardboard, plastic, foam, or the like. In one example, stiffener layers 662 and 669 can include a layer of acrylonitrile butadiene styrene (ABS) and/or cardboard. In some embodiments, stiffener layers 662 and 669 lend rigidity and padding to case 100 to provide protection for electrical device 150 (FIGS. 1, 4, and 5).

In some examples, outer layer 661, stiffener layer 662, and inner layer 663 are stitched together. In other examples, some or all of outer layer 661, stiffener layer 662, and inner layer 663 can be attached together with an adhesive, for example, instead of or in addition to stitching.

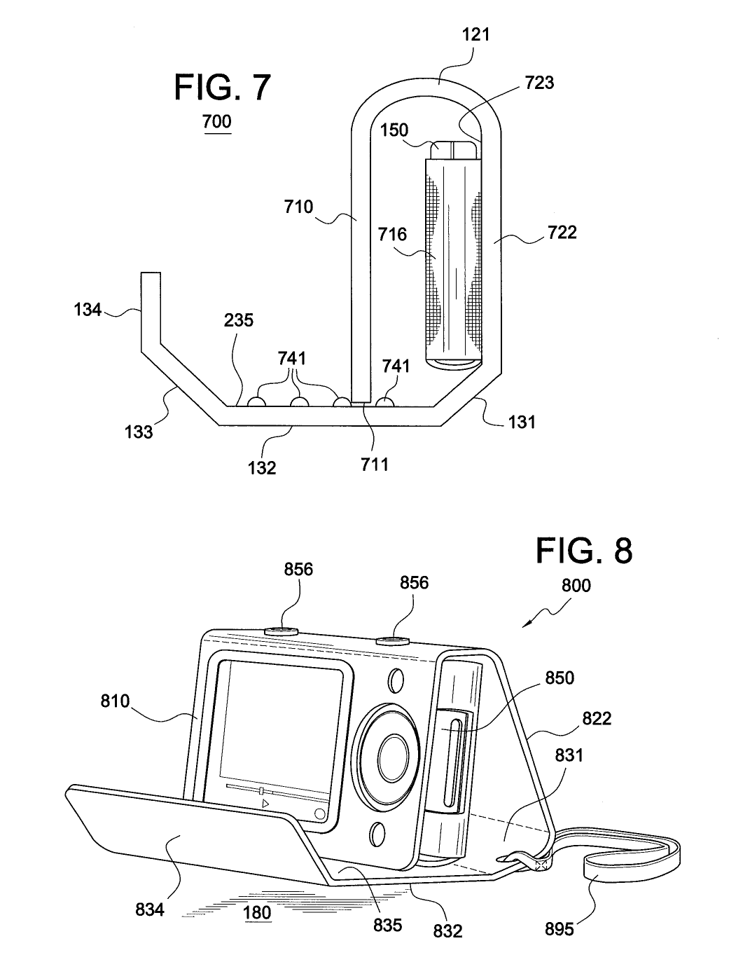

Turning to another embodiment, FIG. 7 illustrates a side view of a case 700 in an open configuration and enclosing electrical device 150, according to a second embodiment of case 100 (FIG. 1). Case 700 can include: (a) an inner portion 710 with a bottom surface 711; (b) an outer portion 722; (c) portions 121, 131, 132, 133, and 134; and (d) at least four ribs 741 at portion 132. When case 700 is placed in an open configuration, inner portion 710 is capable of being located over portion 132 with bottom surface 711 adjacent to interior surface 235.

In this embodiment, outer portion 722 is configured to be removably coupled to electrical device 150. In the example illustrated in FIG. 7, outer portion 722 can include a coupling mechanism 716 (e.g., a pocket) at an interior surface 723. In one example, coupling mechanism 716 can be identical to or substantially similar to coupling mechanism 116 (FIG. 1). In some embodiments, outer portion 722 can include openings (not shown) identical to or substantially similar to openings 271 and 272 (FIG. 2).

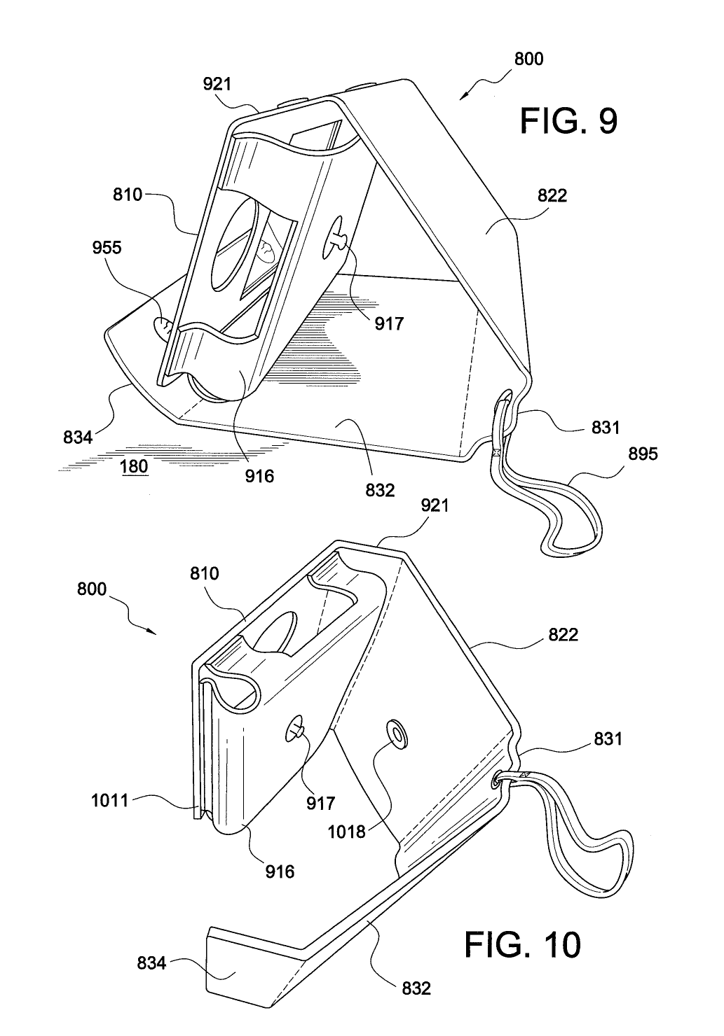

Turning to a further embodiment, FIG. 8 illustrates a top, front, side isometric view of a case 800 in a first embodiment of an open configuration and enclosing an electrical device 850, according to a third embodiment of case 100 (FIG. 1). FIG. 9 illustrates a top, back, side isometric view of case 800 in a second embodiment of the open configuration, according to the third embodiment of case 100 (FIG. 1). FIG. 10 illustrates a bottom, side isometric view of case 800 in a third embodiment of the open configuration, according to the third embodiment of case 100 (FIG. 1). In the embodiment illustrated in FIGS. 8-10, case 800 is configured to enclose electrical device 850. In some examples, electrical device 850 can have a different shape and/or size than electrical device 150 (FIGS. 1 and 5).

In some examples, case 800 can include: (a) an inner portion 810 with an coupling mechanism 916 and a bottom surface 1011; (b) a portion 921 adjacent to inner portion 810; (c) a portion 822 adjacent to portion 921; (d) a portion 831 adjacent to portion 822; (e) a portion 832 with an interior surface 835 and adjacent to portion 831; and (f) a portion 834 adjacent to portion 832. In some examples, case 800 does not include a portion similar to portion 133 (FIG. 1) and/or ribs 241, 242, and 343 (FIGS. 2 and 3) at portion 832. In alternative embodiments, case 800 can include portion 133 (FIG. 1) and/or ribs 241, 242, and/or 343 (FIGS. 2 and 3). When case 800 is placed in an open configuration, inner portion 810 is capable of being located over portion 832 with bottom surface 1011 adjacent to interior surface 835.

In some examples, coupling mechanism 916 can be identical to or substantially similar to coupling mechanism 116 (FIG. 1). In the same or different examples, an attachment mechanism 917 can be located at or adjacent to coupling mechanism 916. Portion 822 can include an attachment mechanism 1018 configured to be coupled to attachment mechanism 917. In some examples, portion 831 can include a coupling mechanism 895 configured to facilitate easy carrying of case 800 and electrical device 850 by a user.

Portion 834 can include a coupling mechanism 955, and a portion 921 can include a coupling mechanism 856. Coupling mechanism 955 can be configured to be coupled to coupling mechanism 856 to secure case 800 in the closed configuration. In some embodiments, attachment mechanisms 917 and 1018 can also be coupled to help hold case 800 in the closed configuration.

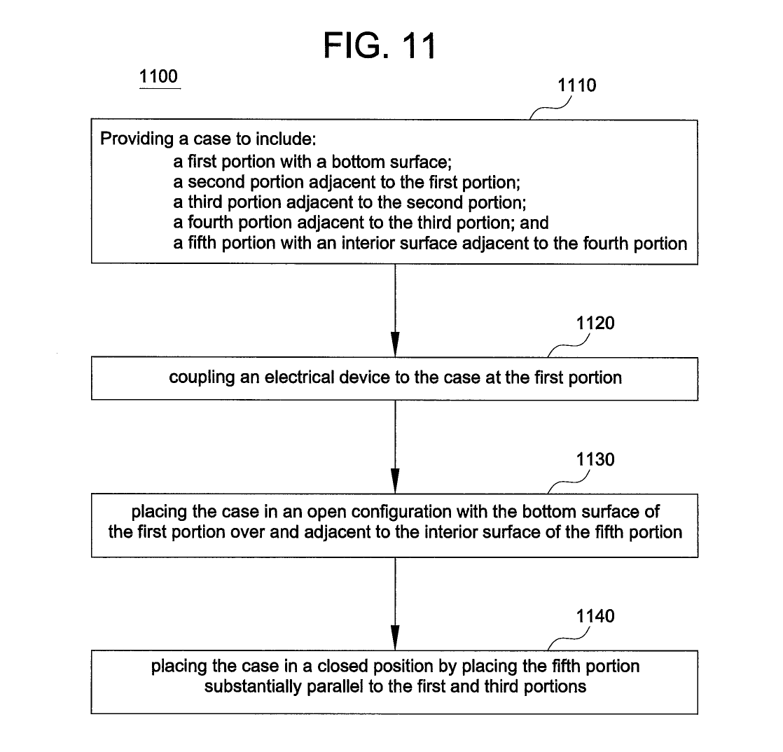

FIG. 11 illustrates a flow chart 1100 for an embodiment of a method of using a case with an electrical device. Flow chart 1100 includes a step 1110 of providing a case to include: (a) a first portion with a bottom surface; (b) a second portion adjacent to the first portion; (c) a third portion adjacent to the second portion; (d) a fourth portion adjacent to the third portion; and (e) a fifth portion with an interior surface and adjacent to the fourth portion. As an example, the case can be similar to cases 100, 700, or 800 of FIGS. 1, 7, and 8, respectively. In some embodiments, the first portion can be similar to inner portions 110, 710 or 810 of FIGS. 1, 7, and 8, respectively. Likewise, the second portion can be similar to portions 121 or 921 of FIGS. 1 and 9, respectively. The third portion can be similar to outer portions 122, 722, or 822 of FIGS. 1, 7, and 8, respectively. The fourth portion can be similar to portions 131 or 831 of FIGS. 1 and 8, respectively. The fifth portion can be similar to portions 132 or 832 of FIGS. 1 and 8, respectively. In the same or a different embodiment, the bottom surface can be similar to bottom surfaces 111, 711, or 1011 of FIGS. 1, 7, and 10, respectively, and the interior surface can be similar to interior surfaces 235, and 835 of FIGS. 2 and 8, respectively.

Flow chart 1100 in FIG. 11 continues with a step 1120 of coupling the electrical device to the case. As an example, the electrical device can be coupled to the case similar to the coupling of electrical devices 150 and 850 to portions 110 or 810 in FIGS. 1 and 8, respectively. In an alternative example, the electrical device can be coupled to the case similar to the coupling of electrical device 150 to outer portion 722 in FIG. 7. For example, the electrical device can be coupled to the case using an attachment mechanism similar to coupling mechanisms 116, 716, or 916 of FIGS. 1, 7, and 9, respectively.

Subsequently, flow chart 1100 includes a step 1130 of placing the case in an open configuration with the bottom surface of the first portion over and adjacent to the interior surface of the fifth portion. As an example, the case can be placed in an open configuration similar to the open configuration of case 100 in FIGS. 2, 3, and 5, case 700 in FIG. 7, and case 800 in FIGS. 8 and 9. In some embodiments, placing the bottom surface of the first portion over and adjacent to the interior surface of the fifth portion can be similar to the configuration of inner portion 110, portion 132, bottom surface 111, and interior surface 235 as shown in FIGS. 2, 3, and 5. In other embodiments, placing the bottom surface of the first portion over and adjacent to the interior surface of the fifth portion can be similar to the configuration of inner portion 710, portion 132, bottom surface 711 and interior surface 235 as shown in FIG. 7. In still further embodiments, placing the bottom surface of the first portion over and adjacent to the interior surface of the fifth portion can be similar to the configuration of inner portion 810, portion 832, bottom surface 1011, and interior surface 835 as shown in FIG. 8, 9, or 10.

In some embodiments, placing the case in the open configuration can also include removably attaching the first portion to the third portion. As an example, the first portion can be removably attached to the third portion similar to the coupling of inner portion 110 to portion 122 as shown in FIG. 5.

Next, flow chart 1100 includes a step 1140 of placing the case in a closed configuration by placing the fifth portion substantially parallel to the first and third portions. As an example, the case can be placed into the closed configuration similar to the closed portion of case 100 as shown in FIG. 4. In some examples, placing the fifth portion substantially parallel to the first and third portions can be similar to the placement of portion 132 substantially parallel to portions 110 and 122, as shown in FIG. 4.

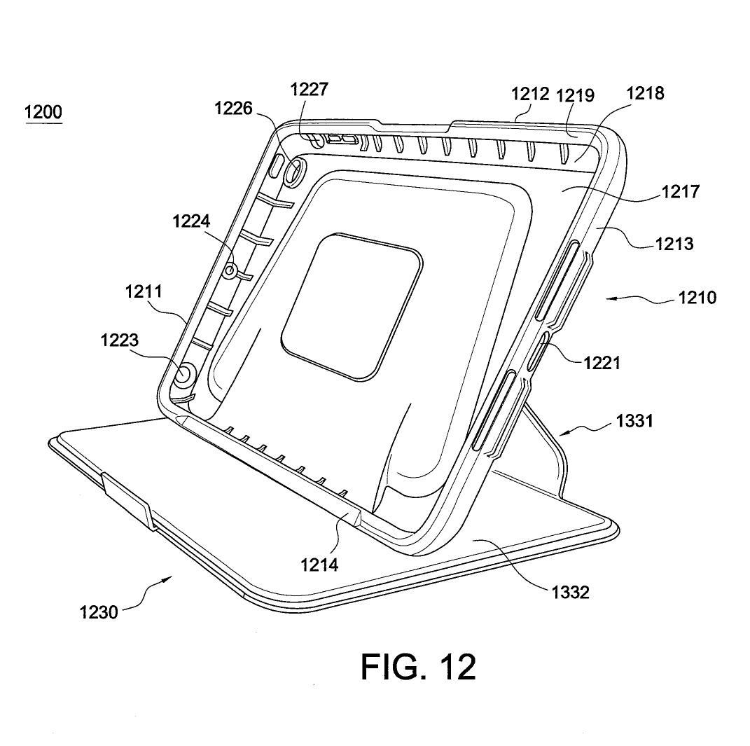

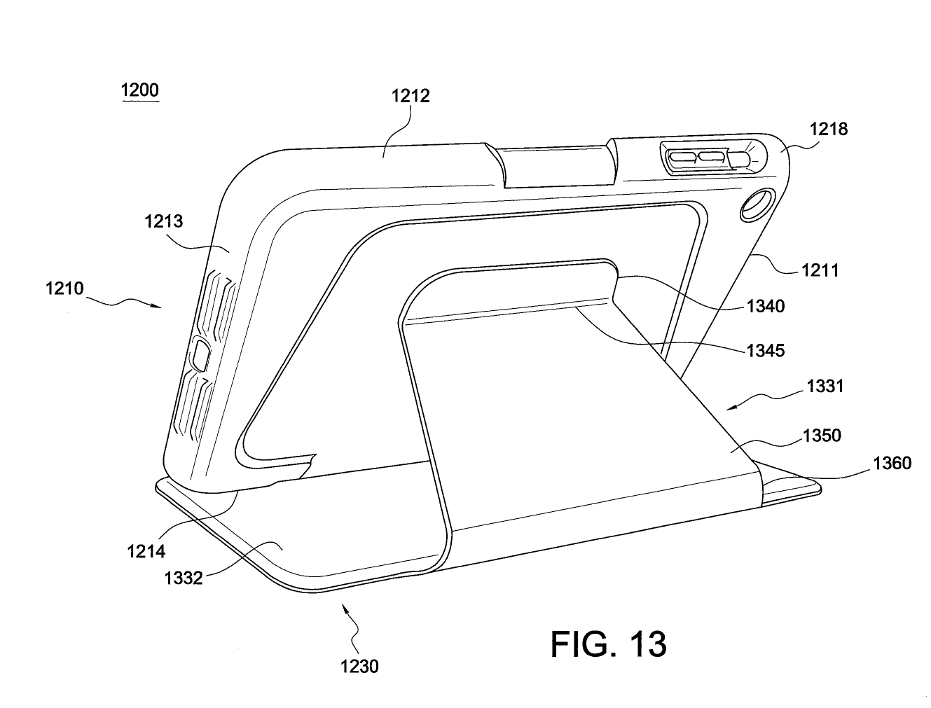

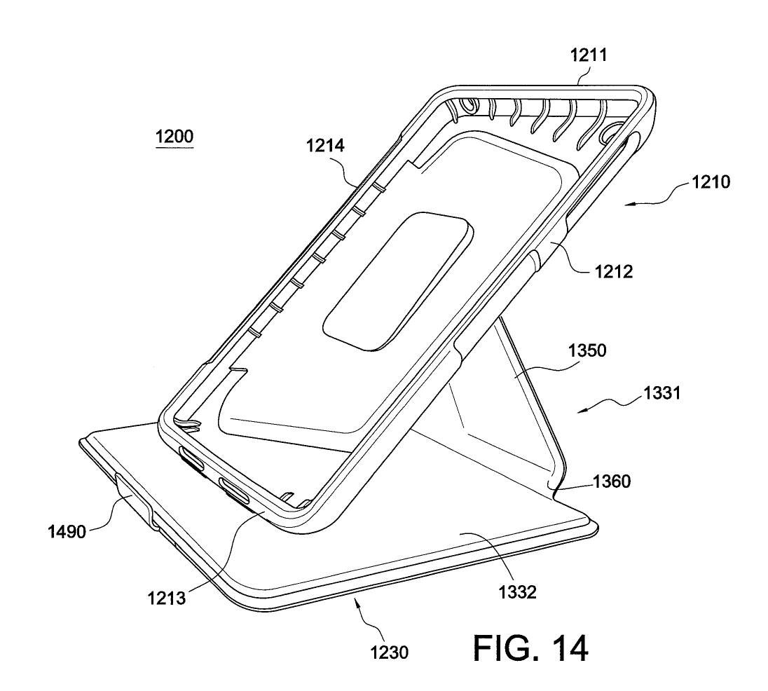

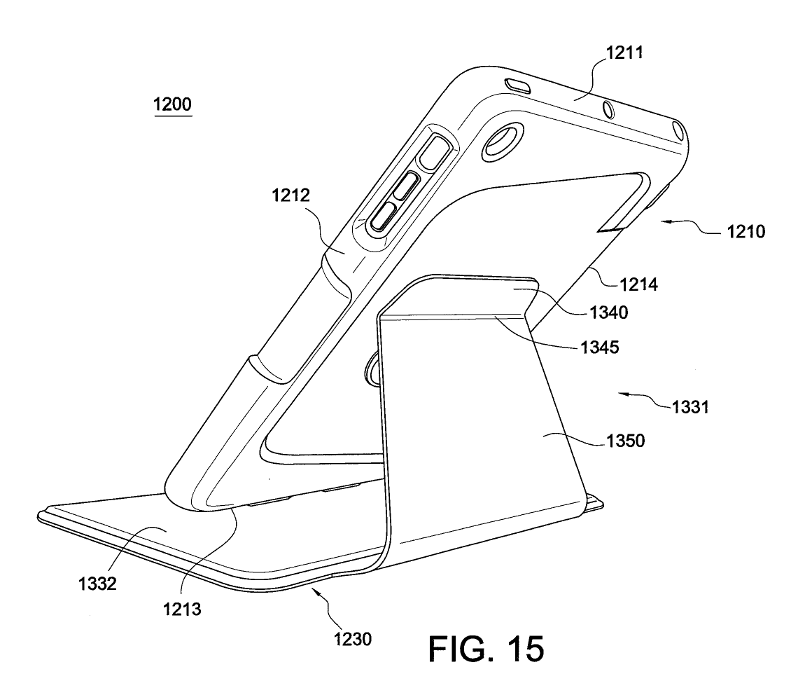

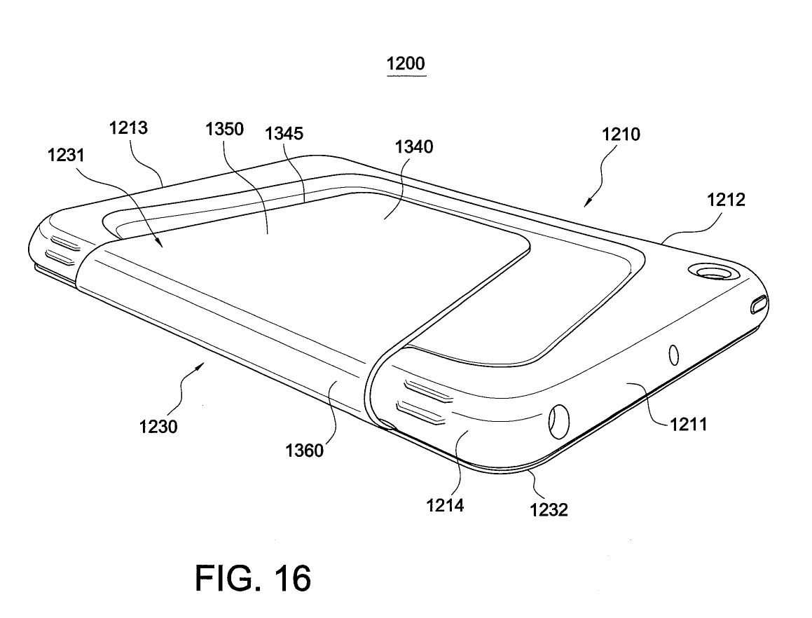

FIG. 12 illustrates various elements of a tablet computer rotatable case 1200 in a landscape viewing configuration. FIG. 13 illustrates various elements of tablet computer rotatable case 1200 in a landscape viewing configuration. FIG. 14 illustrates various elements of tablet computer rotatable case 1200 in a portrait viewing configuration. FIG. 15 illustrates various elements of tablet computer rotatable case 1200 in a portrait viewing configuration. These figures illustrate an example of an apparatus for supporting, in multiple orientations, an electrical device having a touch screen (e.g., a tablet computer). In some embodiments, tablet computer rotatable case 1200 can include tablet support assembly 1210 and tablet case cover 1230. In a number of embodiments, tablet support assembly 1210 can be removably attached to tablet case cover 1230. In certain embodiments, tablet support assembly 1210 can be detached from tablet case cover 1230 and reattached to tablet case cover 1230 in a different orientation. As used herein, removably attached means that the two assemblies can be taken apart and put back together by an ordinary user without any tools and without damaging any components of the assemblies.

In certain embodiments, tablet support assembly can include, as shown in FIG. 12, a tablet support back 1217, one or more tablet support sides 1218, and a tablet support front perimeter 1219. Tablet support back 1217 can provide a back support for the tablet computing device. Tablet support sides 1218 can extend outward from tablet support back 1217, and tablet support front perimeter 1219 can wrap inward from tablet support sides 1218 around the front corners and/or edges of the tablet computing device sufficiently to receive and fittingly secure the tablet computing device in tablet support assembly 1210. Tablet support back 1217, tablet support sides 1218, and tablet support front perimeter 1219 can be connected to each other, and in some embodiments can be molded or otherwise formed as one piece. Tablet support assembly 1210 can include a tablet support first edge 1211, a tablet support second edge 1212 adjacent to tablet support first edge 1211, a tablet support third edge 1213 adjacent to tablet support second edge 1212 and opposite tablet support first edge 1211, and a tablet support fourth edge 1214 adjacent to tablet support third edge 1213 and tablet support first edge 1211, and opposite tablet support second edge 1212. The distance from tablet support first edge 1211 to tablet support third edge 1213 can be greater, in some embodiments, than the distance from tablet support second edge 1212 to tablet support fourth edge 1214. In a landscape orientation in a viewing configuration (as shown in FIGS. 12-13), tablet support second edge 1212 can be located above tablet support fourth edge 1214, and tablet support first edge 1211 can be to the left of tablet support third edge 1213 when viewing the front of tablet support assembly 1210. Tablet support assembly 1210 can be made of a suitable rigid polymer (e.g., polycarbonate (PC) or ABS), metal (e.g., aluminum), ceramic material, thermoplastic elastomer (TPE) (e.g., thermoplastic polyurethane (TPU), and/or semi-rigid polymer.

In certain embodiments, tablet support back 1217, tablet support sides 1218, and/or tablet support front perimeter 1219 can include various holes, grooves, apertures, and/or slots which can allow a user to control the tablet device and/or to connect plugs for peripherals or other connectors to the tablet computing device when it is secured in tablet support assembly 1210, and which can provide an aperture to allow sound waves and/or electromagnetic waves, such as light, to pass through. For example, tablet support assembly 1210 can include various slots for an iPad Mini, including a dock connector slot 1221 configured to allow a Lightning docking cable to connect to the iPad Mini's dock connector, an audio slot 1223 configured to allow an audio jack to connect the iPad Mini's audio receptacle, a microphone slot 1224 configured to allow sound to pass through tablet support assembly 1210 to the iPad Mini's microphone, a camera slot 1226 configured to allow light to pass through tablet support assembly 1210 to the iPad Mini's back camera, and a button slot 1227 configured to allow a user to manipulate volume buttons on the iPad Mini. In other embodiments, various other holes, grooves, and/or slots are included for various other configurations of tablet computing devices.

In a number of embodiments, tablet case cover 1230 can include, as shown in FIG. 13, a tablet case back cover 1331, a tablet case front cover 1332, and a spine 1360. Tablet case front cover 1332 can have a dimension substantially similar to tablet support assembly 1210, and can in some embodiments fully cover the tablet computing device when tablet computer rotatable case 1200 is in a closed configuration, as shown in FIG. 16, described below. Tablet case front cover 1332 can provide a support base for tablet computer rotatable case 1200 when used in a viewing configuration (as shown in FIGS. 12-15). Tablet case back cover 1331 can be connected to tablet case front cover 1332 by spine 1360. Spine 1360 can be of sufficient dimension between tablet case front cover 1332 and tablet case back cover 1331 such that it can extend around tablet support assembly 1210. In some embodiments, tablet case back cover 1331 can have a width less than the distance from between tablet support second edge 1212 and tablet support fourth edge 1214, such that tablet case back cover 1331 can be narrower or shorter than tablet support assembly 1210 when tablet computer rotatable case 1200 is used in a portrait orientation of a viewing configuration, as shown in FIGS. 14-15. In some embodiments, spine 1360 can have a dimension substantially similar to tablet support sides 1218. Back cover 1331 can include back cover first region 1340 and back cover second region 1350. When tablet computer rotatable case 1200 is used in a viewing configuration, back cover first region 1340 can be located above back cover second region 1350. Back cover first region 1340 can be coupled to back cover second region 1350 at back cover hinge 1345.

In various embodiments, tablet case back cover 1331 can fold axially around back cover hinge 1345, and tablet case cover 1230 can fold axially around spine 1360. In some embodiments, tablet support assembly 1210 can be positioned in a landscape orientation in a viewing configuration, as shown in FIGS. 12-13, such that tablet support fourth edge 1214 touches the inner surface of tablet case front cover 1332. In a different configuration, tablet support assembly 1210 can be rotated one hundred eighty degrees where tablet support second edge 1212 touches the inner surface of tablet case front cover 1332 for a different landscape orientation. In many embodiments, spine 1360 can provide an axial hinge for back cover second region 1350, allowing back cover second region 1350 to adjust to various angles relative to back cover first region 1340 and tablet case front cover 1332. Spine 1360 and back cover hinge 1345 can allow tablet support assembly 1210 to be adjusted to various viewing angles relative to tablet case front cover 1332, such that tablet support fourth edge 1214 can rest upon various portions of the inner surface of tablet case front cover 1332 and such that back cover second region 1350 can prop up the back side of tablet support assembly 1210 at various angles. In some viewing configurations, back cover first region 1340 can form a substantially right angle with back cover second region 1350. In other viewing configurations, tablet support assembly 1210 can be positioned at a more upright viewing position, such that back cover first region 1340 forms an obtuse angle with back cover second region 1350 at back cover hinge 1345. In other viewing configurations, tablet support assembly 1210 can be positioned at a less upright viewing position, such that back cover first region 1340 forms an acute angle with back cover second region 1350 at back cover hinge 1345. The viewing angle of tablet support assembly 1210 can be adjusted to provide a comfortable viewing or operating position for a user of the tablet computing device. When in a viewing configuration, tablet computer rotatable case 1200 can thus allow a user to view the tablet computing device at various viewing angles.

In some embodiments, back cover first region 1340, back cover second region 1350, tablet case front cover 1332, and/or spine 1360 can be made of leather (for example, split leather), suede, PVC, polypropylene, polyethylene, nylon, fabric, or another such suitable material. In a number of embodiments, these portions of tablet case cover 1230 can be made of two or more layers of the same or different such materials. The portions can include stiffener layers between the layers to provide additional structural support. For example, back cover first region 1340, back cover second region 1350, and tablet case front cover 1332 can include stiffener layers between the layers to provide structural support, but spine 1360 and back cover hinge 1345 can, in certain embodiments, include layers of fabric without inner stiffener layers, so as to allow flexible hinges. Stiffener layers can be made of a suitable rigid or semi-rigid material, such as cardboard, ABS, plastic, foam, or another such suitable material. In certain embodiments, the layers can be stitched together or attached together with an adhesive. For example, the inner surfaces of certain portions of tablet case cover 1230 (e.g., 1332), can be composed of grip suede, and the outer surfaces can be composed of fabric. These inner and outer layers can be stitched together and/or adhered surrounding an interior layer of plastic used to provide structural support.

In a portrait orientation in a viewing configuration, as shown in FIGS. 14-15, tablet support first edge 1211 can be located above tablet support third edge 1213, and tablet support fourth edge 1214 can be to the left of tablet support second edge 1212 when viewing the front of tablet support assembly 1210. As described above, spine 1360 and back cover hinge 1345 can allow tablet support assembly 1210 to be adjusted to various viewing angles. In a portrait orientation, third edge 1213 can touch the inner surface of tablet case front cover 1332, and can be adjusted to different positions on tablet case front cover 1332 such that back cover first region 1340 can form various angles with back cover second region 1350, as described above. In a different configuration, tablet support assembly 1210 can be rotated one hundred eight degrees where tablet support first edge 1211 can touch the inner surface of tablet case front cover 1332 for a different portrait orientation. The viewing angle of tablet support assembly 1210 can thus be adjusted to provide a comfortable viewing or operating position for a user of the tablet computing device in landscape and/or portrait orientation.

Tablet case cover 1230 can include a flap 1490, which can be attached to tablet case front cover 1332 opposite spine 1260, which can extend around tablet support assembly 1210 and one of the tablet support sides 1218, such as at tablet support second edge 1212, when tablet computer rotatable case 1200 is in a closed configuration (as shown in FIG. 16 and described below). In certain embodiments, flap 1490 can be made of a rigid material and can fittingly secure tablet support assembly 1210 at tablet support side 1218. In other embodiments, flap 1490 can include a magnet that can magnetically couple with a magnet in tablet support assembly 1210 to secure tablet computer lap stand case 1200 in a closed configuration. In other embodiments, flap 1490 can include one or more fasteners, such as hook-and-loop tape and/or one or more snaps, to secure flap 1490 in place and to secure tablet computer lap stand case 1200 in a closed configuration.

FIG. 16 illustrates tablet computer rotatable case 1200 in a closed configuration. In various embodiments in the closed configuration, the inner surface of tablet case front cover 1232 can rest against and/or be positioned in close proximity to and substantially parallel to the front side of tablet support assembly 1210. In a closed configuration, in some embodiments, tablet support fourth edge 1214 can rest against or be positioned in close proximity to the inner side of spine 1360, and tablet support second edge 1212 can rest against or be in close proximity to flap 1490. In a different closed configuration, tablet support assembly 1210 can be rotated one hundred eighty degrees such that tablet support second edge 1212 can rest against or be in close proximity to the inner side of spine 1360. In a number of embodiments, when tablet computer rotatable case 1200 is in a closed configuration, it can securely hold and partially or fully surround the tablet computing device. A closed configuration can, in various embodiments, provide protection for the tablet computing device and its screen from damage.

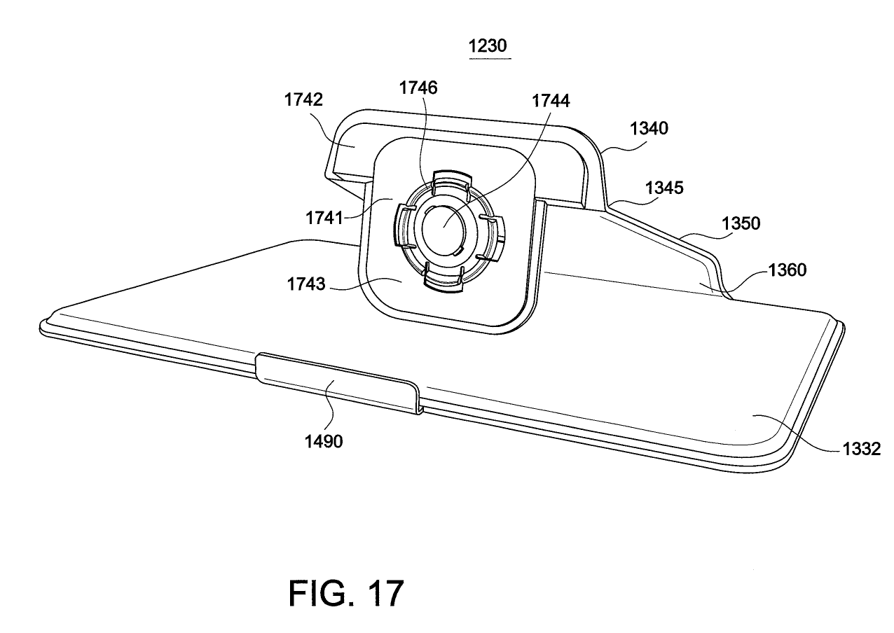

FIG. 17 illustrates various elements of tablet case cover 1230 when detached from tablet support assembly 1210 (FIGS. 12-16). Tablet case cover 1230 can include tablet cover attachment frame 1741. Tablet cover attachment frame 1741 can include an attachment frame first region 1742 and an attachment frame second region 1743. Tablet cover attachment frame 1741 can be attached to back cover first region 1340 and can be substantially parallel with back cover first region 1340. In some embodiments, tablet cover attachment frame 1741 and back cover first region 1340 can be molded as one piece. In a number of embodiments, tablet cover attachment frame 1741 can be attached to back cover first region 1340 at attachment frame first region 1742, but not at attachment frame second region 1743. Attachment frame first region 1742 can extend from the top of back cover first region 1340 to back cover hinge 1345. In certain embodiments, the inner side of back cover second region 1350 can include a recess to accommodate all or part of tablet cover attachment frame 1741 such that back cover first region 1340 and back cover second region 1350 can fold out axially on back cover hinge 1345 to be co-planar with each other, with tablet cover attachment frame 1741 fitting within the recess in back cover second region 1350.

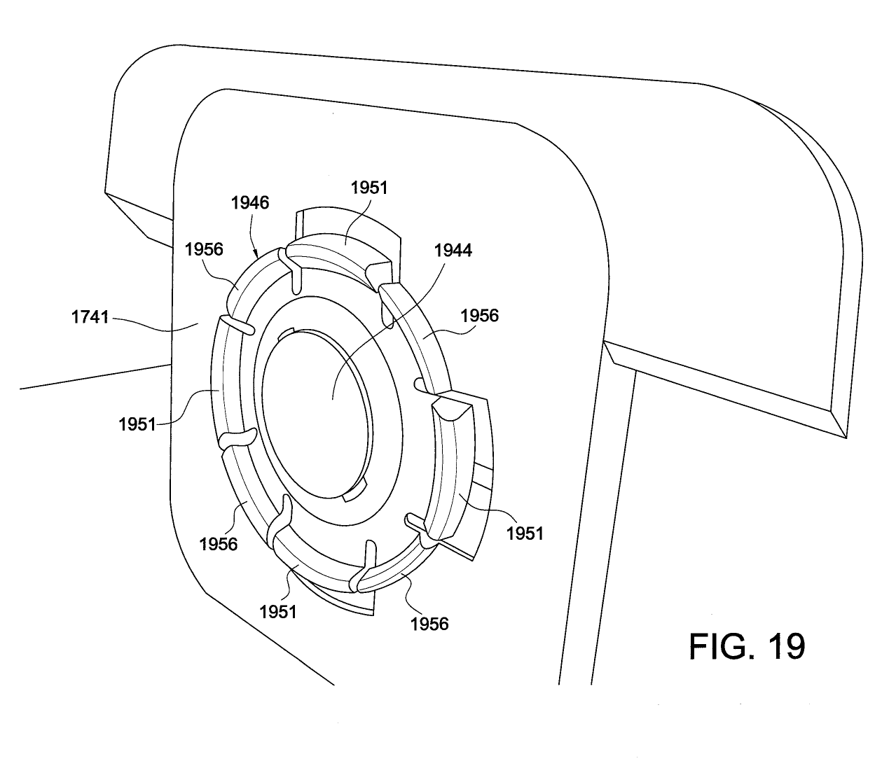

In a number of embodiments, tablet cover attachment frame 1741 can include a cover connector 1744 and a cover alignment piece 1746, as shown in greater detail in FIG. 19 and described below. In various embodiments, tablet cover attachment frame 1741 can be centered between the sides of tablet case cover 1230, and cover connector 1744, and/or cover alignment piece 1746 can be centered on tablet cover attachment frame 1741. In certain embodiments, cover connector 1744 and/or cover alignment piece 1746 can be positioned on tablet cover attachment frame 1741 such that they are centered on attachment frame second region 1743. This position can advantageously allow back cover second region 1350 to attach at hinge 1345 above the center of tablet support assembly 1210 (FIG. 12-15) when it is attached to tablet cover attachment frame 1741, which can provide greater support and help prevent tablet support assembly from tipping back during use.

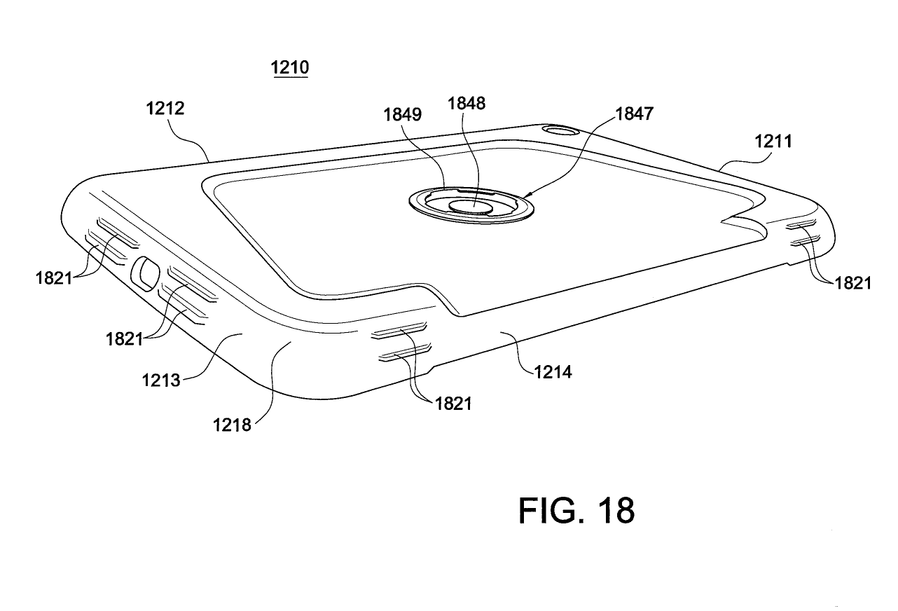

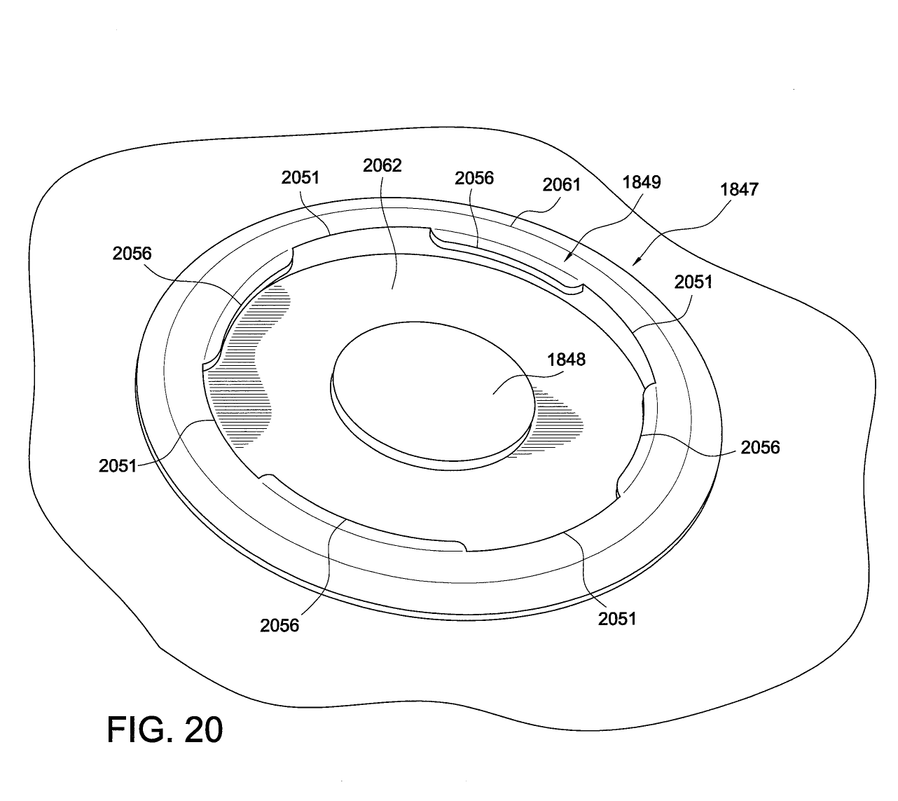

FIG. 18 illustrates various elements of tablet support assembly 1210 when detached from tablet case cover 1230. In some embodiments, tablet support assembly 1210 can include a tablet support attachment piece 1847. Tablet support attachment piece 1847 can be centered between tablet support first side 1211 and tablet support third side 1213, and/or between tablet support second side 1212 and tablet support fourth side 1214. In a number of embodiments, tablet support attachment piece 1847 can include a tablet support connector 1848 and a tablet support alignment piece 1849, as shown in greater detail in FIG. 20 and described below. In certain embodiments, tablet support connector 1848 can be configured to connect with cover connector 1744. Cover connector 1744 and tablet support connector 1848 can, in various embodiments, comprise any suitable set of connectors (e.g., magnets, buttons, etc.) for attaching tablet case cover 1230 to tablet support assembly 1210.

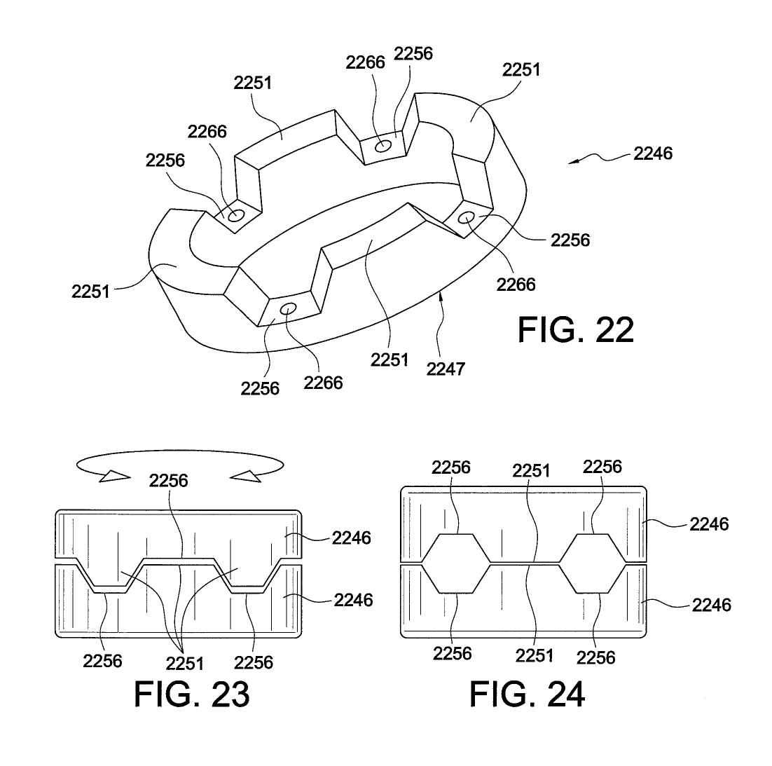

In various embodiments, cover alignment piece 1746 can be configured to engage with tablet support alignment piece 1849 such that tablet support assembly 1210 can attach to tablet case cover 1230 (FIG. 17) in certain predefined orientations, such as a landscape orientation (as shown in FIG. 12-13, described above) and a portrait orientation (as shown in FIG. 14-15, described above). Cover alignment piece 1746 and tablet support alignment piece 1849 can, in various embodiments, comprise any suitable set of alignment pieces for aligning tablet support assembly 1210 in certain orientations with respect to tablet case cover 1230. In a number of embodiments, cover alignment piece 1746 and tablet support alignment piece 1849 can inhibit tablet support assembly 1210 from rotating with respect to tablet case cover 1230 when connected to tablet case cover 1230. In certain embodiments, cover connector 1744 and cover alignment piece 1746 can be the same piece, and/or tablet support connector 1848 and tablet support alignment piece 1849 can be the same piece, as shown in FIGS. 22-24 and described below. In a number of embodiments, tablet support assembly 1210 can include one or more protrusions 1821 on one or more sides of sides 1218. Protrusions 1821 can rest upon tablet case front cover 1332 (FIG. 13) when tablet computer rotatable case is in a viewing configuration, as shown in FIGS. 12-15, and can provide additional support to prevent tablet support assembly 1210 from slipping.

FIG. 19 illustrates various elements of tablet cover attachment frame 1741, including cover connector 1744 and cover alignment piece 1746. FIG. 20 illustrates various elements of tablet support attachment piece 1847, including tablet support connector 1848 and tablet support alignment piece 1849. Cover connector 1744 can be a magnet, such as a magnet having a diameter of approximately 15 millimeters (mm) and a thickness of approximately 2 mm. Similarly, tablet support connector 1848 can be a magnet, such as a magnet having a diameter of approximately 15 millimeters (mm) and a thickness of approximately 2 mm. In other embodiments, the magnets can have another suitable dimension. Cover connector 1744 and tablet support connector 1848 can magnetically couple to provide a secure connection between tablet case cover 1230 and tablet support assembly 1210. In a number of embodiments, cover connector 1744 can be raised with respect to tablet cover attachment frame 1741, and tablet support connector 1848 can be recessed with respect to tablet support alignment piece 1849. In other embodiments, tablet support connector 1848 can be raised and cover connector 1744 can be recessed, flush with, or slightly raised with respect to tablet cover attachment frame 1741. In certain embodiments, one of cover connector 1744 or tablet support connector 1848 can be a suitable metal plate, such as a steel plate, to which the other one of cover connector 1744 or tablet support connector 1848 magnet can magnetically couple. Cover connector 1744 can be centered between cover alignment piece 1746, and/or tablet support connector 1848 can be centered between tablet support alignment piece 1849. In certain embodiments, cover connector 1744 can be magnetically coupled to tablet support connector 1848 only when cover alignment piece 1746 is engaged with tablet support alignment piece 1849, as described below.

In FIG. 19, cover alignment piece 1746 can include outer tabs 1951 and inner tabs 1956, which can be raised with respect to tablet cover attachment frame 1741. Outer tabs 1951 can extend further radially from the center of cover alignment piece 1746 than inner tabs 1956. In many embodiments, each of outer tabs 1951 can extend the same distance radially from the center of cover alignment piece 1746 as each of the other outer tabs, and/or each of inner tabs 1956 can extend the same distance radially from the center of cover alignment piece 1746 as each of the other inner tabs. In a number of embodiments, each of outer tabs 1951 can be equally spaced around cover alignment piece 1745 and interleaved between inner tabs 1956, which can also each be equally spaced around cover alignment piece 1746. In FIG. 20, tablet support alignment piece 1849 can include an outer ring 2061 and an inner recess 2062. Outer ring 2061 can include notches 2051 and protrusions 2056. Each of notches 2051 can be equally spaced around outer ring 2061 and interleaved between each of protrusions 2056, which can also be equally spaced around outer ring 2061, such that each of outer tabs 1951 (FIG. 19) of cover alignment piece 1746 (FIG. 19) can fit within each of notches 2051 in inner recess 2062 and between each of protrusions 2056. Specifically, in many embodiments, the radial distance from the center of tablet support attachment piece 1847 to the inner side of protrusions 2056 can be less than the radial distance from the center of cover alignment piece 1746 (FIG. 19) to the outer edge of outer tabs 1951 (FIG. 19).

The radial distance from the center of tablet support attachment piece 1847 to the inner side of protrusions 2056 can, in a number of embodiments, be greater than the radial distance from the center of cover alignment piece 1746 to the outer edge of inner tabs 1956 (FIG. 19), such that inner tabs 1956 (FIG. 19) can fit within inner recess 2062 within protrusions 2056 such that cover alignment piece 1746 (FIG. 19) and tablet support alignment piece 1849 can be engaged together. Similarly, the radial distance from the center of tablet support attachment piece 1847 to the inner side of the notches 2051 can be greater than the radial distance from the center of cover alignment piece 1746 (FIG. 19) to the outer edge of outer tabs 1951 (FIG. 19), such that outer tabs 1951 (FIG. 19) can fit within inner recess 2062 within notches 2051. When cover alignment piece 1746 (FIG. 19) is engaged within tablet support alignment piece 1849, cover connector 1744 (FIG. 19) and tablet support connector 1848 can be magnetically coupled together, and tablet support assembly 1210 (FIG. 18) can be aligned to certain predefined orientations, such as landscape or portrait orientation. In some embodiments, protrusions 2056 can be spaced such that when cover alignment piece 1746 is engaged with tablet support alignment piece 1849, outer tabs 1951 (FIG. 19) cannot freely rotate, such that tablet support assembly 1210 (FIG. 18) cannot be rotated with respect to tablet cover attachment frame 1741 without being disengaged, such a by decoupling cover connector 1744 and tablet support connector 1848 from each other.

The alignment pieces, such as tablet support alignment piece 1849 and cover alignment piece 1746, can advantageously prevent the free rotation of tablet support assembly 1210 (FIG. 18) when used in a viewing configuration (as shown in FIGS. 12-15, described above). The number of outer tabs can be the same as the number of notches, and the number of inner tabs can be the same as the number of protrusions. In certain embodiments, the number of outer tabs 1951 (FIG. 19), notches 2051, inner tabs 1956 (FIG. 19), and protrusions 2056, can each be four, or a multiple of four, such that tablet support alignment piece can be configured in a landscape (as shown in FIGS. 12-13, described above) and a portrait orientation (as shown in FIGS. 14-15, described above).

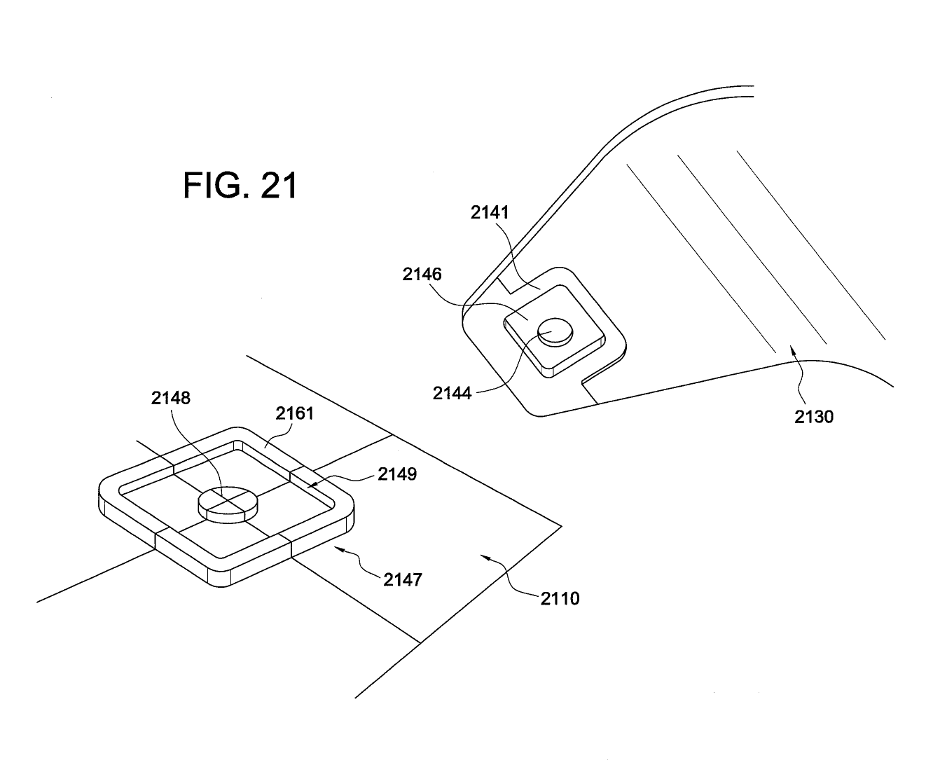

FIG. 21 illustrates a portion of a tablet support assembly 2110 and a portion of a tablet case cover 2130. Tablet support assembly 2110 can be similar to tablet support assembly 1210 (FIG. 12), and various components and/or constructions of tablet support assembly 2110 can be similar or identical to various components of tablet support assembly 1210. Similarly, tablet case cover 2130 can be similar to tablet case cover 1230 (FIG. 12), and various components and/or constructions of tablet case cover 2130 can be similar or identical to various components of tablet case cover 1230. Tablet case cover 2130 can include tablet cover attachment frame 2141, which can be similar to tablet cover attachment frame 1741 (FIG. 17). Tablet cover attachment frame 2141 can include a cover connector 2144 and a cover alignment piece 2146. Tablet support assembly 2110 can include a tablet support attachment piece 2147, which can be similar to tablet support attachment piece 1847 (FIG. 18). Tablet support attachment piece 2147 can include a tablet support connector 2148 and a tablet support alignment piece 2149. Cover connector 2144 and/or tablet support connector 2148 can be magnets, and can be similar to the magnets described above for cover connector 1746 (FIG. 17) and tablet support connector 1848 (FIG. 18). In some embodiments, cover connector 2144 can be raised with respect to tablet cover attachment frame 2141, and tablet support connector 2148 can be recessed with respect to tablet support alignment piece 2149. In other embodiments, tablet support connector 2148 can be raised and cover connector 2144 can be recessed, flush with, or slightly raised with respect to tablet cover attachment frame 2141. In certain embodiments, one of cover connector 2144 or tablet support connector 2148 can be made of a suitable metal, such as steel, to which the other one of cover connector 2144 or tablet support cover 2148 can magnetically couple.

In some embodiments, cover alignment piece 2146 can be a square-shaped protrusion, and tablet support alignment piece 2149 can include a square ring 2161 to create an inner square recess of similar dimension as cover alignment piece 2146, such that cover alignment piece 2146 can fit within tablet support alignment piece 2149 when cover connector 2144 is magnetically coupled to tablet support connector 2148. In a number of embodiments, cover alignment piece 2146 and outer ring 2161, although substantially square, can have slightly rounded corners. In many embodiments, cover alignment piece 2146 cannot freely rotate while engaged in tablet support alignment piece 2149. In addition to the square-shaped alignment pieces shown in FIG. 21 and described above, and the rounded tabbed alignment pieces shown in FIGS. 19-20, the alignment pieces and/or connector pieces can be any other suitable set of alignment pieces or connector pieces for connecting and aligning the orientation of the tablet support assembly, e.g. 1210 (FIG. 12-15), 2110 (FIG. 21), with respect to the tablet case cover, e.g., 1230 (FIG. 12-15), 2130 (FIG. 21). For example, the tablet support assembly can, in some embodiments, be connected and/or aligned with snaps, suction cups, or hook-and-loop tape.

For example, FIG. 22 illustrates a swivel piece 2246 that can be used as an attachment mechanism for a cover alignment piece (e.g., 1746 (FIG. 17), 2146 (FIG. 21)), for a tablet support alignment piece (e.g., 1849 (FIG. 18), 2149 (FIG. 21)), for a cover connector (e.g., 1744 (FIG. 17), 2144 (FIG. 21)), and/or for a tablet support connector (e.g., 1848 (FIG. 18), 2148 (FIG. 21)). In certain embodiments, swivel piece 2246 can be attached at a swivel based 2247 to a tablet support assembly (e.g., 1210 (FIG. 18), 2110 (FIG. 21)) and a tablet cover attachment frame (e.g., 1741 (FIG. 17), 2141 (FIG. 21)), similarly, and in like position, as tablet support attachment piece 1847 (FIG. 18) is attached to tablet support assembly 1210, and cover connector 1744 and cover alignment piece 1746 (FIG. 17) are attached to tablet cover attachment frame 1741. Swivel mechanism 2246 can, in some embodiments, have a annular shape and can include protrusions 2251, which can be raised above troughs 2256 with respect to swivel base 2247. Each of trough 2256 can, in certain embodiments, include a magnet 2266. Swivel piece 2246 can include slanted and/or rounded edges between protrusions 2251 and troughs 2256. In a number of embodiments, swivel piece 2246 can be made of metal, such as steel, or another suitable material for magnetically coupling with magnets 2266.

In some embodiments, two swivel pieces 2246 can attach and engage with each other by protrusions 2251 of one swivel piece 2246 fitting within troughs 2256 of the other swivel piece 2246, as shown in FIG. 23. In certain embodiments, magnets 2266 in troughs 2256 of one swivel piece 2246 can magnetically couple to protrusions 2251 of the other swivel piece. Each of swivel pieces 2246 can be rotated with respect to each other, but the slanted or curved surfaces between protrusions 2251 and troughs 2256 can increase the distance between magnets 2266 of one swivel piece 2246 and the other swivel piece 2246. When protrusions 2251 of one swivel piece 2246 are touching protrusions 2251 of the other swivel piece 2246, there can, in some embodiments, be a weak magnetic coupling, but the magnetic coupling, in certain embodiments, is not strong enough to hold tablet support assembly (e.g., 1210 (FIG. 18), 2110 (FIG. 21)) to tablet cover attachment frame (e.g., 1741 (FIG. 17), 2141 (FIG. 21)).

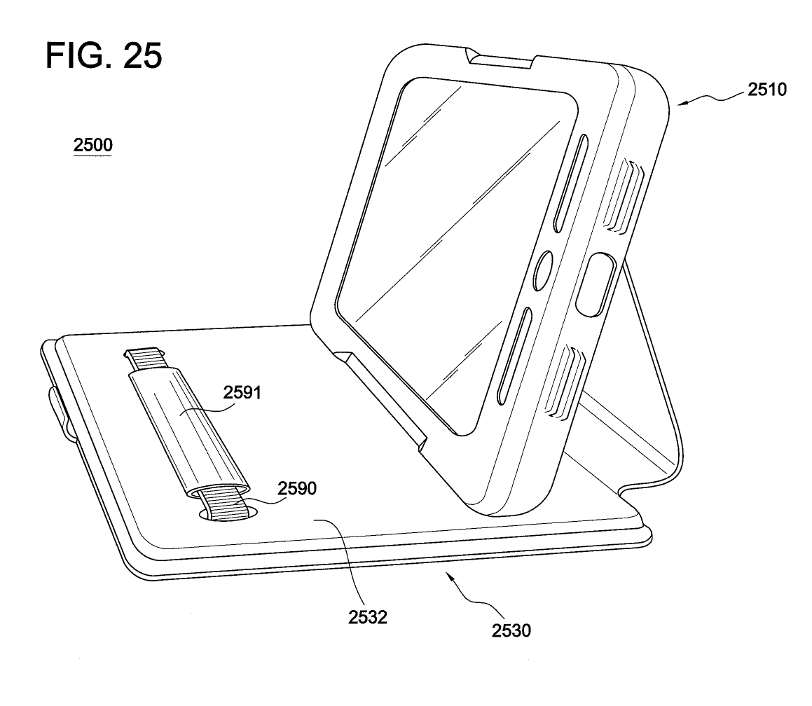

FIG. 25 illustrates tablet computer rotatable case 2500 in a landscape viewing configuration. Tablet computer rotatable case 2500 can be similar to tablet computer rotatable case 1200 (FIG. 12-15), and various components and/or constructions of tablet computer rotatable case 2500 can be similar or identical to various components of tablet computer rotatable case 1200. Tablet computer rotatable case 2500 can include a tablet support assembly 2510 and a tablet case cover 2530. Tablet support assembly 2510 can be similar to tablet support assembly 1210 (FIGS. 12-15) and tablet case cover 2530 can be similar to tablet case cover 1230 (FIGS. 12-15). Tablet case cover 2530 can include tablet case front cover 2532, which can be similar to tablet case front cover 1332 (FIG. 13). In a number of embodiments, tablet case front cover 2532 can include a hand strap 2590, which can extend partially across tablet case front cover 2532 and can be attached to the inner side of tablet case front cover 2532. In other embodiments, hand strap 2590 can be attached to the outer side of tablet case front cover 2532. Hand strap 2590 can be made of a suitable leather or fabric. In some embodiments hand strap 2590 can be made of an elastic ribbon, which can be made of synthetic or natural rubber and a fabric.

In various embodiments, hand strap 2590 can include a contact region 2591, which can be made of a soft and/or padded fabric, or another material suitable for extended contact with a hand. In certain embodiments, contact region can surround hand strap 2590, and can extend partially or fully along hand strap 2590. In certain embodiments, a user can hold hand strap 2590 while using tablet computer rotatable case 2500, such as in a viewing configuration, as shown. The user can hold hand strap 2590, for example, by placing the user's hand between hand strap 2590 (and/or contact region 2591) and tablet case front cover 2532, or by placing the hand around both sides of hand strap 2590 (and/or contact region 2591). In various embodiments, hand strap 2590 can allow the user to prevent portable computer lap stand case 2500 from slipping or being bumped off the user's lap, such as while the riding on a bus on a bumpy road. Hand strap 2590 also can be used, in various embodiments, to extend around tablet support assembly 2510 when tablet computer rotatable case 2500 is in a closed configuration (as shown in FIG. 16 and described above) to securely hold tablet computer rotatable case 2500 in a closed configuration. Other uses for hand strap 2590 are also possible. For example, in another application, front cover 2532 can be folded behind tablet support assembly 2510, and a user's hand can be placed between hand strap 2590 and front cover 2532 to hold tablet computer rotatable case 2500 while viewing and/or otherwise using the tablet computing device held by tablet support assembly 2510.

FIGS. 12 to 25 illustrate particular examples of an apparatus for supporting an electrical device having a touch screen. Such an electrical device can be a tablet computer, for example. In a number of embodiments, the electrical device or tablet computer can be supported in multiple orientations, for example. Tablet computer rotatable case 1200 is an example of such an apparatus. In a number of embodiments, the apparatus includes base (e.g., tablet case cover 1230), a back member (e.g., tablet case back cover 1331), a first hinge (e.g., spine 1360) attaching the back member to the base, a cover (e.g., tablet support assembly 1210) configured to hold the electrical device, and a connector (e.g., including cover connector 1744, tablet support connector 1848, or both).

In a number of embodiments, the base is substantially planar. As used herein, “substantially planar” means within the same plane, to within 0.75 inches in either direction from the plane. Further, as used herein, “planar”, without being preceded by the word “substantially”, means within the same plane, to within 0.375 inches, in either direction, from the plane. In some embodiments, the base, back member, or both, are planar. Moreover, in some embodiments, the back member is substantially planar. Even further, in some embodiments, when the hinge or hinges (e.g., the first hinge) is unfolded so that the apparatus is laid flat, the apparatus is substantially planar. Further still, in particular embodiments, when the first hinge is unfolded so that the base and the back member are laid flat, the base and the back member are substantially planar. Even further still, in certain embodiments, when the first hinge is unfolded, the base and the back member are planar.

In various embodiments, the connector attaches the cover to the back member and includes at least one alignment piece (e.g., cover alignment piece 1746, tablet support alignment piece 1849, or both, or other alignment pieces described herein) that aligns the cover to the back member only in certain predefined orientations. Thus, the alignment pieces do not allow the cover to be rotated continuously with reference to the back member, for example, or to be assembled in any position, but just allow the cover to be positioned or attached to the back member in these certain predefined orientations. In some embodiments, for example, the predefined orientations include a landscape orientation (e.g., shown in FIGS. 12, 13, and 25) and a portrait orientation (e.g., shown in FIGS. 14 and 15). As used herein, in the landscape orientation (e.g., shown in FIGS. 12, 13, and 25) the longest sides of the electrical device are horizontal (i.e., to within 10 degrees), and in the portrait orientation (e.g., shown in FIGS. 14 and 15) the shortest sides of the electrical device are horizontal (i.e., to within 10 degrees).

In a number of embodiments, the alignment piece inhibits the cover from being rotated (i.e., without detaching the cover or damaging any components) about an axis perpendicular to the cover (e.g., the axis being through the center of the connector, through the center of the cover, or both), such rotation being relative to the back member, when the cover is attached to the back member with the connector. But, in various embodiments, the connector allows the cover to be detached from the back member (i.e., non-destructively) and reattached (i.e., without tools or additional materials), for example, in a different one of the predefined orientations. In various embodiments, the connector allows the cover to be detached from the back member and reattached, as an alternative, in the same predefined orientation as well, at the option of the user.

In some embodiments, the cover includes a center (e.g., where tablet support connector 1848 is shown in FIG. 18, or at the center thereof) and the connector (e.g., tablet support connector 1848 shown in FIG. 18) is located at the center of the cover. Further, in a number of embodiments, the connector includes a first piece committedly connected to the cover and a second piece committedly connected to the back member, and the first piece is separated from the second piece when the cover is detached from the back member. As used herein, “committedly connected” means integral with or connected in a manner that a typical user does not separate the two parts in the ordinary use of the apparatus. Further, as used herein, two parts are considered to be “committedly connected” if tools or destruction of components or breaking of an adhesive bond is required to separate the two parts.

Further still, in some embodiments, the first piece of the connector has a central first axis (e.g., where tablet support connector 1848 is shown in FIG. 18, at the center thereof), the second piece has a central second axis (e.g., where cover connector 1744 is shown in FIG. 17, at the center thereof). In some embodiments, the first axis and the second axis are in common when the cover is attached to the back member by the connecter. Even further, in some embodiments, the first piece has a first magnet (e.g., 1848) concentric with the first axis and the second piece has a second magnet (e.g., 1744) concentric with the second axis, and when the cover is attached to the back member by the connecter, the first magnet is magnetically bonded to the second magnet. In some embodiments, for example, the magnets are touching. In other embodiments, the magnets are in close proximity, i.e., sufficiently close to hold the cover on the base and back member in ordinary use supporting the electrical device. Even further still, in particular embodiments, the alignment piece is concentric with the first axis and the second axis when the cover is attached to the back member by the connecter and the first magnet is magnetically bonded to the second magnet (e.g., as shown in FIGS. 17-21, and also true for the embodiment shown in FIGS. 22-24).

In various embodiments, the connector includes at least one magnet, and the at least one magnet holds the connector in the predefined orientations (i.e., in one such orientation at a time). In some embodiments, for example, the cover includes a center and the at least one magnet includes a first magnet concentric with the center of the cover. Examples are shown in FIGS. 17-21. Further, in different embodiments, at least one magnet includes a first magnet and either a second magnet or a piece of iron or magnetic steel, as examples. For instance, if tablet support connector 1848 is a magnet, mating cover connector 1744 can be a magnet or a piece of iron or steel, in different embodiments, or vice versa. Even further, in some embodiments, the first magnet significantly bonds with the second magnet or the piece of iron or magnetic steel only when the cover is aligned to the back member, for instance, in the certain predefined orientations. As used herein, “substantially bonds” means bonding adequately to attach the cover to the back member sufficiently to support the electrical device in normal use. Thus, in these embodiments, the apparatus can be used, with the cover attached to the back member and base, only in one of the certain predefined orientations (e.g., portrait and landscape).

In certain embodiments, the at least one alignment piece includes multiple outer tabs (e.g., 1951) and multiple inner tabs (e.g., 1956). See, for example, FIGS. 17 and 19. In the embodiment illustrated, the outer tabs alternate with the inner tabs, and the outer tabs extend further radially from the center than the inner tabs. Moreover, in the embodiment shown, the outer tabs are equally spaced around the center and the inner tabs are equally spaced around the center. Other embodiments may differ. Further, in the embodiment depicted, the at least one alignment piece includes four of the outer tabs and four of the inner tabs. Other embodiments have an even number of the outer tabs, an even number of the inner tabs, a multiple of four of the outer tabs, a multiple of four of the inner tabs, two of the outer tabs, two of the inner tabs, eight of the outer tabs, eight of the inner tabs, twelve of the outer tabs, twelve of the inner tabs, one of the outer tabs, one of the inner tabs, or a combination thereof, as examples.

Further, in some embodiments, the at least one alignment piece includes an outer ring (e.g., 2061) and an inner recess (e.g., 2062). FIG. 20 illustrates an example. In particular embodiments, for example, and in the embodiment illustrated, the outer ring (e.g., 2061) includes alternating notches (e.g., 2051) and protrusions (e.g., 2056) spaced around the outer ring. Even further, in certain embodiments, a first radial distance from the center of the connector to a first inner side of the protrusions is less than a second radial distance from the center of the connector to a second inner side of the notches. Still further, in some embodiments, the outer tabs (e.g., 1951 shown in FIG. 19) fit within the inner recess (e.g., 2062) at the notches, and the inner tabs fit within the inner recess at the protrusions, but the outer tabs do not fit within the inner recess at the protrusions.

Even further, in some embodiments, the at least one alignment piece includes a non-circular recess concentric with the center and a mating non-circular protrusion. FIG. 21 illustrates an example. In various embodiments, the protrusion (e.g., square ring 2161) mates with the recess (e.g., 2141) in a first orientation and a second orientation, and the first orientation and the second orientation are 90 degrees apart (i.e., within plus or minus 5 degrees, as used herein). Moreover, in various embodiments, the apparatus further includes a hand strap (e.g., 2590, shown in FIG. 25, or as described herein).

Still further, in some embodiments, the at least one alignment piece includes a first ring concentric with the center of the connector. An example of such a ring is piece 2246 shown in FIG. 22. In certain embodiments, for example, the first ring includes alternating protrusions (e.g., 2251) and toughs (e.g., 2256), for example, extending around the center of the connector. Moreover, in particular embodiments, the first ring includes multiple magnets (e.g., 2266) located, for instance, in the toughs around the center of the connector. Furthermore, in specific embodiments, the first ring includes at least four toughs around the center of the connector (e.g., evenly spaced around the center), for example, as shown in FIG. 22. Even further still, in some embodiments, the at least one alignment piece includes a second ring (e.g., 2246 shown in FIGS. 23 and 24), for example, concentric with the center of the connector. In particular embodiments, the second ring includes alternating protrusions (e.g., 2051) and toughs (e.g., 2056) extending around the center of the connector. Further, in certain embodiments, the second ring mates with the first ring with protrusions of the first rings in troughs of the second ring and protrusions of the second rings in troughs of the first ring (e.g., as shown in FIG. 23). Although not shown as such, in some embodiments, the troughs and protrusions have equal or substantially equal dimensions, for example, in the tangential direction around the center, the first and second rings have the same size troughs and projections, or both. In the position shown in FIG. 24, in the embodiment illustrated, magnets 2266 are separated sufficiently that an adequate magnetic bond does not exist. In this manner, the cover is detached from the back member and the cover is not aligned in one of the certain predefined orientations.

Further embodiments provide various methods. An example is a method of obtaining, providing, or manufacturing an apparatus for supporting an electrical device having a touch screen in multiple orientations. In a number of embodiments, such a method includes at least the acts of obtaining, providing, or manufacturing a base (e.g., tablet case cover 1230), obtaining, providing, or manufacturing a back member (e.g., tablet case back cover 1331) attached to the base, obtaining, providing, or manufacturing a cover (e.g., tablet support assembly 1210) configured to hold the electrical device, and obtaining, providing, or manufacturing a connector (e.g., including cover connector 1744, tablet support connector 1848, or both). In a number of embodiments, the connector attaches the cover to the back member and aligns the cover to the back member only in certain predefined orientations, the predefined orientations including a landscape orientation (e.g., shown in FIGS. 12, 13, and 25) and a portrait orientation (e.g., shown in FIGS. 14 and 15). Further, in various embodiments, the connector inhibits the cover from being rotated about an axis perpendicular to the cover relative to the back member when the cover is attached to the back member with the connector, but the connector allows the cover to be detached from the back member and reattached in multiple of the predefined orientations.

Although the invention has been described with reference to specific embodiments, it will be understood by those skilled in the art that various changes may be made without departing from the spirit or scope of the invention. For example, to one of ordinary skill in the art, it will be readily apparent portion 133 and portion 121 can include other complementary coupling mechanisms in addition to or instead of coupling mechanisms 355 and 356. Additional examples of such changes have been given in the foregoing description. Accordingly, the disclosure of embodiments of the invention is intended to be illustrative of the scope of the invention and is not intended to be limiting. It is intended that the scope of the invention shall be limited only to the extent required by the appended claims. To one of ordinary skill in the art, it will be readily apparent that the case and method of use discussed herein may be implemented in a variety of embodiments, and that the foregoing discussion of certain of these embodiments does not necessarily represent a complete description of all possible embodiments. Rather, the detailed description of the drawings, and the drawings themselves, disclose at least one preferred embodiment of the invention, and may disclose alternative embodiments of the invention.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. An apparatus for supporting an electrical device having a touch screen in multiple orientations, the apparatus comprising:
a substantially planar base;
a back member;
a first hinge attaching the back member to the base;
a cover configured to hold the electrical device; and
a connector that attaches the cover to the back member, the connector comprising at least one alignment piece that aligns the cover to the back member only in certain predefined orientations, the predefined orientations including a landscape orientation and a portrait orientation, wherein the alignment piece inhibits the cover from being rotated about an axis perpendicular to the cover relative to the back member when the cover is attached to the back member with the connector, but the connector allows the cover to be detached from the back member and reattached in a different one of the predefined orientations.

2. The apparatus of claim 1 wherein the cover comprises a center and wherein the connector is located at the center of the cover.

3. The apparatus of claim 1 wherein the connector comprises a first piece committedly connected to the cover and a second piece committedly connected to the back member, wherein the first piece is separated from the second piece when the cover is detached from the back member.

4. The apparatus of claim 3 wherein the first piece has a central first axis, the second piece has a central second axis, the first axis and the second axis are in common when the cover is attached to the back member by the connecter and wherein the first piece has a first magnet concentric with the first axis and the second piece has a second magnet concentric with the second axis, and wherein when the cover is attached to the back member by the connecter, the first magnet is magnetically bonded to the second magnet.

5. The apparatus of claim 4 wherein the alignment piece is concentric with the first axis and the second axis when the cover is attached to the back member by the connecter and the first magnet is magnetically bonded to the second magnet.

6. The apparatus of claim 1 wherein the connector comprises at least one magnet, wherein the at least one magnet holds the connector in the predefined orientations.

7. The apparatus of claim 6 wherein the cover comprises a center and wherein the at least one magnet comprises a first magnet concentric with the center of the cover.

8. The apparatus of claim 6 wherein the at least one magnet comprises a first magnet and either a second magnet or a piece of iron or magnetic steel.

9. The apparatus of claim 6 wherein the first magnet significantly bonds with the second magnet or the piece of iron or magnetic steel only when the cover is aligned to the back member in the certain predefined orientations.

10. The apparatus of claim 1 wherein the connector comprises a center and wherein the at least one alignment piece comprises multiple outer tabs and multiple inner tabs, wherein the outer tabs alternate with the inner tabs, and wherein the outer tabs extend further radially from the center than the inner tabs.

11. The apparatus of claim 10 wherein the outer tabs are equally spaced around the center and wherein the inner tabs are equally spaced around the center.

12. The apparatus of claim 10 wherein the at least one alignment piece comprises four of the outer tabs and four of the inner tabs.

13. The apparatus of claim 10 wherein the at least one alignment piece comprises an outer ring and an inner recess wherein the outer ring comprises alternating notches and protrusions spaced around the outer ring, wherein a first radial distance from the center of the connector to a first inner side of the protrusions is less than a second radial distance from the center of the connector to a second inner side of the notches, and wherein the outer tabs fit within the inner recess at the notches, and the inner tabs fit within the inner recess at the protrusions, but the outer tabs do not fit within the inner recess at the protrusions.

14. The apparatus of claim 1 wherein the connector comprises a center and wherein the at least one alignment piece comprises a non-circular recess concentric with the center and a mating non-circular protrusion, wherein the protrusion mates with the recess in a first orientation and a second orientation, wherein the first orientation and the second orientation are 90 degrees apart.

15. The apparatus of claim 1 wherein the connector comprises a center and wherein the at least one alignment piece comprises a first ring concentric with the center of the connector, wherein the first ring comprises alternating protrusions and toughs extending around the center of the connector.

16. The apparatus of claim 15 wherein the first ring comprises multiple magnets located in the toughs around the center of the connector.

17. The apparatus of claim 15 wherein the first ring comprises at least four toughs around the center of the connector.

18. The apparatus of claim 15 wherein the at least one alignment piece comprises a second ring concentric with the center of the connector, wherein the second ring comprises alternating protrusions and toughs extending around the center of the connector, and wherein the second ring mates with the first ring with protrusions of the first rings in troughs of the second ring and protrusions of the second rings in troughs of the first ring.

19. The apparatus of claim 1 further comprising a hand strap.

20. A method of obtaining, providing, or manufacturing an apparatus for supporting an electrical device having a touch screen in multiple orientations, the method comprising at least the acts of:
obtaining, providing, or manufacturing a base;
obtaining, providing, or manufacturing a back member attached to the base;
obtaining, providing, or manufacturing a cover configured to hold the electrical device; and
obtaining, providing, or manufacturing a connector that attaches the cover to the back member and aligns the cover to the back member only in certain predefined orientations, the predefined orientations including a landscape orientation and a portrait orientation, wherein the connector inhibits the cover from being rotated about an axis perpendicular to the cover relative to the back member when the cover is attached to the back member with the connector, but the connector allows the cover to be detached from the back member and reattached in multiple of the predefined orientations.
